(19) United States
(12) Patent Application Publication
(10) Pub. No.: US 2018/0066359 A1
(43) Pub. Date: Mar. 8, 2018

(54) METHOD OF DEPOSITING THIN FILM

(71) Applicant: ASM IP Holding B.V., Almere (NL)

(72) Inventors: Dae Youn KIM, Daejeon (KR); Seung Woo CHOI, Cheonan-si (KR); Young Hoon KIM, Cheonan-si (KR); Seiji OKURA, Sagamihara-shi (JP); Hyung Wook NOH, Anyang-si (KR); Dong Seok KANG, Cheonan-si (KR)

(21) Appl. No.: 15/807,896

(22) Filed: Nov. 9, 2017

Related U.S. Application Data
(62) Division of application No. 14/285,831, filed on May 23, 2014, now abandoned.

(30) Foreign Application Priority Data
Nov. 6, 2013 (KR) 10-2013-0134388

(51) Int. Cl. C23C 16/30; C23C 16/455; C23C 16/50

(52) U.S. Cl. CPC C23C 16/308; C23C 16/45523; C23C 16/50

(57) ABSTRACT

Disclosed is a method of depositing a thin film, which includes supplying a purge gas and a source gas into a plurality of reactors for a first period, stopping supplying of the source gas, and supplying the purge gas and a reaction gas into the plurality of reactors for a second period, and supplying the reaction gas and plasma into the plurality of reactors for a third period.

### CROSS-REFERENCE TO RELATED APPLICATION

This application is a Divisional Application of U.S. patent application Ser. No. 14/285,831 filed on May 23, 2014, which claims priority to and the benefit of Korean Patent Application No. 10-2013-0134388 filed in the Korean Intellectual Property Office on Nov. 6, 2013, the entire contents of which are incorporated herein by reference.

### BACKGROUND OF THE INVENTION

### (a) Field of the Invention

The present invention relates to a method of depositing a thin film.

### (b) Description of the Related Art

A silicon oxynitride (SiON) film used as an anti-reflective coating (ARC) and a gate silicon oxinitride (SiON) film during a semiconductor process is deposited by a plasma enhanced chemical vapor deposition (PECVD) method.

The plasma enhanced chemical vapor deposition method is a method where raw gases and plasma are simultaneously and successively supplied to a reactor to deposit a thin film.

However, when the raw gases are simultaneously supplied to perform deposition, a step coverage property and an uniformity of a thickness of a film deposited on a substrate is deteriorated. Further, when a multi-chamber deposition device including a plurality of reactors is used in one deposition device, uniformity of the deposited film may be reduced among the reactors (chambers), and reproducibility is reduced among the reactors.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a method of depositing a thin film, in which a step coverage property is improved and a film with uniform feature across the substrate is deposited so that deposition reproducibility among reactors can be improved by finely adjusting a thickness and uniformity of the deposited thin film.

An exemplary embodiment of the present invention provides a method of depositing a thin film. The method includes supplying a purge gas and a source gas into a plurality of reactors for a first period, stopping supplying of the source gas, and supplying the purge gas and a reaction gas into a plurality of reactors for a second period, and supplying the reaction gas and plasma into a plurality of reactors for a third period.

The source gas may be a precursor including silicon, and the reaction gas may include at least one of a gas including nitrogen or a gas including oxygen and the purge gas may comprise an inert gas.

The source gas may comprise at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DIPAS, SiH₃N(iPr)₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; TEOS, Si(OEt)₄; SiCl₄; HCD, Si₂Cl₆; MCS, SiH₃Cl; DCS, SiH₂Cl₂; 3DMAS, SiH(N(Me)₂)₃; BEMAS, SiH₂[N(Et)(Me)]₂; AHEAD, Si₂(NHEt)₆; TEAS, Si(NHEt)₄; and Si₃H₈.

The source gas may comprise at least one of SiI₄, HSiI₃, H₂SiI₂, H₃SiI, Si₂I₆, HSi₂I₅, H₂Si₂I₄, H₃Si₂I₃, H₄Si₂I₂, H₅Si₂I, Si₃I₈, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, HMe₂SiI, HMeSi₂I₄, HMe₂Si₂I₃, HMe₃Si₂I₂, HMe₄Si₂I, H₂MeSiI, H₂MeSi₂I₃, H₂Me₂Si₂I₂, H₂Me₃Si₂I, H₃MeSi₂I₂, H₃Me₂Si₂I, H₄MeSi₂I, EtSiI₃, Et₂SiI₂, Et₃SiI, EtSi₂I₅, Et₂Si₂I₄, Et₃Si₂I₃, Et₄Si₂I₂, Et₅Si₂I, HEtSiI₂, HEt₂SiI, HEtSi₂I₄, HEt₂Si₂I₃, HEt₃Si₂I₂, HEt₄Si₂I, H₂EtSiI, H₂EtSi₂I₃, H₂Et₂Si₂I₂, H₂Et₃Si₂I, H₃EtSi₂I₂, H₃Et₂Si₂I and H₄EtSi₂I.

The source gas may comprise at least one of EtMeSiI₂, Et₂MeSiI, EtMe₂SiI, EtMeSi₂I₄, Et₂MeSi₂I₃, EtMe₂Si₂I₃, Et₃MeSi₂I₂, Et₂Me₂Si₂I₂, EtMe₃Si₂I₂, Et₄MeSi₂I, Et₃Me₂Si₂I, Et₂Me₃Si₂I, EtMe₄Si₂I, HEtMeSiI, HEtMeSi₂I₃, HEt₂MeSi₂I₂, HEtMe₂Si₂I₂, HEt₃MeSi₂I, HEt₂Me₂Si₂I, HEtMe₃Si₂I, H₂EtMeSi₂I₂, H₂Et₂MeSi₂I, H₂EtMe₂Si₂I, H₃EtMeSi₂I.

The source gas may comprise two, three, four, five, six, seven, eight, nine, ten, eleven, twelve, thirteen, fourteen, fifteen, sixteen, seventeen, eighteen, nineteen or more compounds selected from HSiI₃, H₂SiI₂, H₃SiI, H₂Si₂I₄, H₄Si₂I₂, H₅Si₂I, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, H₂Me₂Si₂I₂, EtSiI₃, Et₂SiI₂, Et₃SiI, Et₂Si₂I₄, Et₄Si₂I₂ and HEtSiI₂, including any combinations thereof.

The reaction gas may comprise at least one of N₂, NO, N₂O NO₂, N₂H₄, NH₃ and N₂/H₂ mixture, O₂, CO, CO₂, and O₃ or a combination thereof.

The method may further include supplying the purge gas and the reaction gas into a plurality of reactors for the first period.

The method may further include supplying the purge gas into a plurality of reactors for a fourth period.

The method may further include supplying the purge gas into a plurality of reactors for the fourth period.

Another exemplary embodiment of the present invention provides a method of depositing a thin film. The method includes supplying a purge gas and a source gas into a plurality of reactors for a first sub-period, stopping supplying of the source gas, and supplying the purge gas and a first reaction gas into the plurality of reactors for a second sub-period, supplying the first reaction gas and plasma into the plurality of reactors for a third sub-period, supplying the purge gas and the source gas into the plurality of reactors for a fifth sub-period, stopping supplying of the source gas, and supplying the purge gas into the plurality of reactors for a sixth sub-period, and supplying the purge gas and the plasma into the plurality of reactors for a seventh sub-period.

The method may further comprises supplying a second reaction gas into the plurality of reactors for the sixth sub-period and the seventh sub-period.

The source gas may be a precursor including silicon, the first reaction gas may be a gas including oxygen. The second reaction gas may be a gas including nitrogen.

The source gas may comprise at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DIPAS, SiH₃N(iPr)₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; TEOS, Si(OEt)₄; SiCl₄; HCD, Si₂Cl₆; MCS, SiH₃Cl; DCS, SiH₂Cl₂; 3DMAS, SiH(N(Me)₂)₃; BEMAS, SiH₂[N(Et)(Me)]₂; AHEAD, Si₂(NHEt)₆; TEAS, Si(NHEt)₄; and Si₃H₈.

The source gas may comprise one or more of the following: SiI₄, HSiI₃, H₂SiI₂, H₃SiI, Si₂I₆, HSi₂I₅, H₂Si₂I₄, H₃Si₂I₃, H₄Si₂I₂, H₅Si₂I, Si₃I₈, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, HMe₂SiI, HMeSi₂I₄, HMe₂Si₂I₃, HMe₃Si₂I₂, HMe₄Si₂I, H₂MeSiI, H₂MeSi₂I₃, H₂Me₂Si₂I₂, H₂Me₃Si₂I, H₃MeSi₂I₂, H₃Me₂Si₂I, H₄MeSi₂I, EtSiI₃, Et₂SiI₂, Et₃SiI, EtSi₂I₅, Et₂Si₂I₄, Et₃Si₂I₃, Et₄Si₂I₂, Et₅Si₂I, HEtSiI₂, HEt₂SiI, HEtSi₂I₄, HEt₂Si₂I₃, HEt₃Si₂I₂, HEt₄Si₂I, H₂EtSiI, H₂EtSi₂I₃, H₂Et₂Si₂I₂, H₂Et₃Si₂I, H₃EtSi₂I₂, H₃Et₂Si₂I and H₄EtSi₂I.

The source gas may comprise one or more of the following: EtMeSiI₂, Et₂MeSiI, EtMe₂SiI, EtMeSi₂I₄, Et₂MeSi₂I₃, EtMe₂Si₂I₃, Et₃MeSi₂I₂, Et₂Me₂Si₂I₂, EtMe₃Si₂I₂, Et₄MeSi₂I, Et₃Me₂Si₂I, Et₂Me₃Si₂I, EtMe₄Si₂I, HEtMeSiI, HEtMeSi₂I₃, HEt₂MeSi₂I₂, HEtMe₂Si₂I₂, HEt₃MeSi₂I, HEt₂Me₂Si₂I, HEtMe₃Si₂I, H₂EtMeSi₂I₂, H₂Et₂MeSi₂I, H₂EtMe₂Si₂I, H₃EtMeSi₂I.

The source gas may comprise two, three, four, five, six, seven, eight, nine, ten, eleven, twelve, thirteen, fourteen, fifteen, sixteen, seventeen, eighteen, nineteen or more compounds selected from HSiI₃, H₂SiI₂, H₃SiI, H₂Si₂I₄, H₄Si₂I₂, H₅Si₂I, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, H₂Me₂Si₂I₂, EtSiI₃, Et₂SiI₂, Et₃SiI, Et₂Si₂I₄, Et₄Si₂I₂ and HEtSiI₂, including any combinations thereof.

The first reaction gas may include at least one of O₂, CO, CO₂, N₂O, H₂O and O₃. The second reaction gas may include at least one of N₂, NO, NO₂ N₂H₄, NH₃, and N₂/H₂ mixture.

The purge gas may include an inert gas and a hydrogen or oxygen gas.

The inert gas may be a second reaction gas in an inactive state.

The purge gas may be the second reaction gas in an inactive state.

In the method, a first gas supply cycle including the first sub-period, the second sub-period, and the third sub-period, and a second gas supply cycle including the fifth sub-period, the sixth sub-period, and the seventh sub-period may be alternately repeated.

The first gas supply cycle may further comprise supplying the purge gas into the plurality of reactors for a fourth sub-period, and the second gas supply cycle may further comprise supplying the purge gas into the plurality of reactors for an eighth sub-period.

The method may comprise supplying a second reaction gas into the plurality of reactors for the sixth sub-period and the seventh sub-period.

The method may comprise repeating a first gas supply cycle including the first sub-period, the second sub-period, and the third sub-period for first plural times, and repeating a second gas supply cycle including the fifth sub-period, the sixth sub-period, and the seventh sub-period for second plural times, wherein the repeating of the first gas supply cycle and the repeating of the second gas supply cycle are alternately repeated.

The first plural times and the second plural times may be the same as or different from each other.

Another exemplary embodiment of the present invention provides a method of depositing a thin film. The method comprises supplying a purge gas, a source gas and a first reaction gas into a plurality of reactors for a first sub-period, stopping supplying of the source gas, and supplying the purge gas and the first reaction gas into the plurality of reactors for a second sub-period, supplying the purge gas, the first reaction gas and plasma into the plurality of reactors for a third sub-period, supplying the purge gas and a second reaction gas into the plurality of reactors for a fifth sub-period, and supplying the purge gas, the second reaction gas and the plasma into the plurality of reactors for a seventh sub-period.

The method may further comprise supplying of the source gas into the plurality of reactors for the fifth sub-period.

The source gas may be a precursor including silicon and the first reaction gas may be a gas including nitrogen. The second reaction gas may be a gas including oxygen.

The source gas may comprise at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DIPAS, SiH₃N(iPr)₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; TEOS, Si(OEt)₄; SiCl₄; HCD, Si₂Cl₆; MCS, SiH₃Cl; DCS, SiH₂Cl₂; 3DMAS, SiH(N(Me)₂)₃; BEMAS, SiH₂[N(Et)(Me)]₂; AHEAD, Si₂(NHEt)₆; TEAS, Si(NHEt)₄; and Si₃H₈.

The source gas may comprise at least one of SiI₄, HSiI₃, H₂SiI₂, H₃SiI, Si₂I₆, HSi₂I₅, H₂Si₂I₄, H₃Si₂I₃, H₄Si₂I₂, H₅Si₂I, Si₃I₈, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, HMe₂SiI, HMeSi₂I₄, HMe₂Si₂I₃, HMe₃Si₂I₂, HMe₄Si₂I, H₂MeSiI, H₂MeSi₂I₃, H₂Me₂Si₂I₂, H₂Me₃Si₂I, H₃MeSi₂I₂, H₃Me₂Si₂I, H₄MeSi₂I, EtSiI₃, Et₂SiI₂, Et₃SiI, EtSi₂I₅, Et₂Si₂I₄, Et₃Si₂I₃, Et₄Si₂I₂, Et₅Si₂I, HEtSiI₂, HEt₂SiI, HEtSi₂I₄, HEt₂Si₂I₃, HEt₃Si₂I₂, HEt₄Si₂I, H₂EtSiI, H₂EtSi₂I₃, H₂Et₂Si₂I₂, H₂Et₃Si₂I, H₃EtSi₂I₂, H₃Et₂Si₂I and H₄EtSi₂I.

The source gas may comprise at least one of EtMeSiI₂, Et₂MeSiI, EtMe₂SiI, EtMeSi₂I₄, Et₂MeSi₂I₃, EtMe₂Si₂I₃, Et₃MeSi₂I₂, Et₂Me₂Si₂I₂, EtMe₃Si₂I₂, Et₄MeSi₂I, Et₃Me₂Si₂I, Et₂Me₃Si₂I, EtMe₄Si₂I, HEtMeSiI, HEtMeSi₂I₃, HEt₂MeSi₂I₂, HEtMe₂Si₂I₂, HEt₃MeSi₂I, HEt₂Me₂Si₂I, HEtMe₃Si₂I, H₂EtMeSi₂I₂, H₂Et₂MeSi₂I, H₂EtMe₂Si₂I, H₃EtMeSi₂I.

The source gas may comprise two, three, four, five, six, seven, eight, nine, ten, eleven, twelve, thirteen, fourteen, fifteen, sixteen, seventeen, eighteen, nineteen or more compounds selected from HSiI₃, H₂SiI₂, H₃SiI, H₂Si₂I₄, H₄Si₂I₂, H₅Si₂I, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, H₂Me₂Si₂I₂, EtSiI₃, Et₂SiI₂, Et₃SiI, Et₂Si₂I₄, Et₄Si₂I₂ and HEtSiI₂, including any combinations thereof.

The first reaction gas may comprise at least one of N₂, NO, N₂O, NO₂, N₂H₂, NH₃ and N₂/H₂ mixture, and the second reaction gas may comprise at least one of O₂, CO, CO₂, N₂O and O₃.

The purge gas may comprise an inert gas.

In the method, a first gas supply cycle including the first sub-period, the second sub-period, and the third sub-period, and a second gas supply cycle including the fifth sub-period and the seventh sub-period may be alternately repeated.

The first gas supply cycle may further comprise supplying the purge gas and the first reaction gas into the plurality of reactors for a fourth sub-period, and the second gas supply cycle may further comprise supplying the purge gas and the second reaction gas into the plurality of reactors for a sixth sub-period and an eighth sub-period.

The second gas supply cycle may further comprise supplying the purge gas and the first reaction gas into the plurality of reactors for an eighth sub-period.

The method may further comprise a third gas supply cycle comprising a same sequence of sub-periods as the first gas supply cycle.

The method may comprise repeating a first gas supply cycle including the first sub-period, the second sub-period, and the third sub-period for first plural times, and repeating a second gas supply cycle including the fifth sub-period and the seventh sub-period for second plural times, wherein the repeating of the first gas supply cycle and the repeating of the second gas supply cycle are alternately repeated.

The first plural times and the second plural times may be the same as or different from each other.

The first gas supply cycle may further comprise supplying the purge gas and the first reaction gas into the plurality of reactors for a fourth sub-period, and the second gas supply cycle may further comprise supplying the purge gas and the second reaction gas into the plurality of reactors for an eighth sub-period.

The first reaction gas may comprise at least one of O₂, CO, CO₂, N₂O and O₃, and the second reaction gas may comprise at least one of N₂, NO, N₂O, NO₂, N₂H₂, NH₃ and N₂/H₂ mixture.

The purge gas may comprise an inert gas. In the method, a first gas supply cycle including the first sub-period, the second sub-period, and the third sub-period, and a second gas supply cycle including the fifth sub-period and the seventh sub-period may be alternately repeated.

The first gas supply cycle may further comprise supplying the purge gas into the plurality of reactors for a fourth sub-period, and the second gas supply cycle may further comprise supplying the purge gas into the plurality of reactors for an eighth sub-period.

The method may comprise repeating a first gas supply cycle including the first sub-period, the second sub-period, and the third sub-period for first plural times, and repeating a second gas supply cycle including the fifth sub-period and the seventh sub-period for second plural times, wherein the repeating of the first gas supply cycle and the repeating of the second gas supply cycle are alternately repeated.

The first plural times and the second plural times may be the same as or different from each other.

The first gas supply cycle may further comprise supplying the purge gas into the plurality of reactors for a fourth sub-period, and the second gas supply cycle may further comprise supplying the purge gas into the plurality of reactors for an eighth sub-period.

The method may comprise repeating a first gas supply cycle including the first sub-period and the second sub-period for first plural times, repeating a second gas supply cycle including the third sub-period for second plural times, and repeating a third gas supply cycle including the fifth sub-period and the seventh sub-period for third plural times, wherein the repeating of the first gas supply cycle, the repeating of the second gas supply cycle and the repeating of the third gas supply cycle are alternately repeated.

The first plural times, the second plural times and the third plural times may be the same as or different from each other.

Another exemplary embodiment of the present invention provides a method of depositing a thin film. The method comprises supplying a source gas, a purge gas and a first reaction gas into a plurality of reactors for a first sub-period, stopping supplying of the source gas, and supplying the purge gas and the first reaction gas into the plurality of reactors for a second sub-period, supplying the purge gas, the first reaction gas and plasma into the plurality of reactors for a third sub-period, supplying the purge gas and the first reaction gas into the plurality of reactors for a fifth sub-period, supplying the purge gas, the first reaction gas and a second reaction gas into the plurality of reactors for a sixth sub-period, supplying the purge gas, the first reaction gas, the second reaction gas and plasma into the plurality of reactors for a seventh sub-period, supplying the source gas, the purge gas and the first reaction gas into the plurality of reactors for a ninth sub-period, stopping supplying of the source gas, and supplying the purge gas and the first reaction gas into the plurality of reactors for a tenth sub-period, and supplying the purge gas, the first reaction gas and the plasma into the plurality of reactors for an eleventh sub-period.

The source gas may be a precursor including silicon, the first reaction gas may be a gas including nitrogen, the second reaction gas may be a gas including oxygen, and the purge gas may comprise an inert gas.

In the method, a first gas supply cycle including the first sub-period, the second sub-period and the third sub-period, a second gas supply cycle including the fifth sub-period, the sixth sub-period and the seventh sub-period, and a third gas supply cycle including the ninth sub-period, the tenth sub-period and the eleventh sub-period may be alternately repeated.

The first gas supply cycle may further comprise supplying the purge gas and the first reaction gas into the plurality of reactors for a fourth sub-period, the second gas supply cycle may further comprise supplying the purge gas and the first reaction gas into the plurality of reactors for an eighth sub-period, and the third gas supply cycle may further comprise supplying the purge gas and the first reaction gas into the plurality of reactors for an twelfth sub-period.

The method may comprise repeating a first gas supply cycle including the first sub-period, the second sub-period, and the third sub-period for first plural times, repeating a second gas supply cycle including the fifth sub-period, the sixth sub-period and the seventh sub-period for second plural times, and repeating a third gas supply cycle including the ninth sub-period, the tenth sub-period and the eleventh sub-period for third plural times, wherein the repeating of the first gas supply cycle, the repeating of the second gas supply cycle and the repeating of the third gas supply cycle are alternately repeated.

The first plural times, the second plural times and the third plural times may be the same as or different from each other.

The first gas supply cycle may further comprise supplying the purge gas and the first reaction gas into the plurality of reactors for a fourth sub-period, the second gas supply cycle may further comprise supplying the purge gas and the first reaction gas into the plurality of reactors for an eighth sub-period, and the third gas supply cycle may further comprise supplying the purge gas and the first reaction gas into the plurality of reactors for an twelfth sub-period.

The source gas may comprise at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DIPAS, SiH₃N(iPr)₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; TEOS, Si(OEt)₄; SiCl₄; HCD, Si₂Cl₆; MCS, SiH₃Cl; DCS, SiH₂Cl₂; 3DMAS, SiH(N(Me)₂)₃; BEMAS, SiH₂[N(Et)(Me)]₂; AHEAD, Si₂(NHEt)₆; TEAS, Si(NHEt)₄; and Si₃H₈.

The source gas may comprise at least one of SiI₄, HSiI₃, H₂SiI₂, H₃SiI, Si₂I₆, HSi₂I₅, H₂Si₂I₄, H₃Si₂I₃, H₄Si₂I₂, H₅Si₂I, Si₃I₈, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, HMe₂SiI, HMeSi₂I₄, HMe₂Si₂I₃, HMe₃Si₂I₂, HMe₄Si₂I, H₂MeSiI, H₂MeSi₂I₃, H₂Me₂Si₂I₂, H₂Me₃Si₂I, H₃MeSi₂I₂, H₃Me₂Si₂I, H₄MeSi₂I, EtSiI₃, Et₂SiI₂, Et₃SiI, EtSi₂I₅, Et₂Si₂I₄, Et₃Si₂I₃, Et₄Si₂I₂, Et₅Si₂I, HEtSiI₂, HEt₂SiI, HEtSi₂I₄, HEt₂Si₂I₃, HEt₃Si₂I₂, HEt₄Si₂I, H₂EtSiI, H₂EtSi₂I₃, H₂Et₂Si₂I₂, H₂Et₃Si₂I, H₃EtSi₂I₂, H₃Et₂Si₂I and H₄EtSi₂I.

The source gas may comprise at least one of EtMeSiI₂, Et₂MeSiI, EtMe₂SiI, EtMeSi₂I₄, Et₂MeSi₂I₃, EtMe₂Si₂I₃, Et₃MeSi₂I₂, Et₂Me₂Si₂I₂, EtMe₃Si₂I₂, Et₄MeSi₂I, Et₃Me₂Si₂I, Et₂Me₃Si₂I, EtMe₄Si₂I, HEtMeSiI, HEtMeSi₂I₃, HEt₂MeSi₂I₂, HEtMe₂Si₂I₂, HEt₃MeSi₂I, HEt₂Me₂Si₂I, HEtMe₃Si₂I, H₂EtMeSi₂I₂, H₂Et₂MeSi₂I, H₂EtMe₂Si₂I, H₃EtMeSi₂I.

The source gas may comprise two, three, four, five, six, seven, eight, nine, ten, eleven, twelve, thirteen, fourteen, fifteen, sixteen, seventeen, eighteen, nineteen or more compounds selected from HSiI₃, H₂SiI₂, H₃SiI, H₂Si₂I₄, H₄Si₂I₂, H₅Si₂I, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, H₂Me₂Si₂I₂, EtSiI₃, Et₂SiI₂, Et₃SiI, Et₂Si₂I₄, Et₄Si₂I₂ and HEtSiI₂, including any combinations thereof.

According to a method of depositing a thin film according to the exemplary embodiments of the present invention, it is possible to improve a step coverage property and deposit a film having a uniform feature so that deposition reproducibility among reactors can be improved by finely adjusting a thickness and uniformity of the deposited thin film.

### BRIEF DESCRIPTION OF THE DRAWINGS

FIGS. 1-12 are timing charts showing gas supply cycles to deposit a thin film according to various exemplary embodiments of the present invention.

### DETAILED DESCRIPTION OF THE EMBODIMENTS

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be “directly on” the other element or intervening elements may also be present. In contrast, when an element is referred to as being “directly on” another element, there are no intervening elements present.

Then, a method of depositing a thin film according to an exemplary embodiment of the present invention will be described with reference to the drawings.

First, the method of depositing the thin film according to the exemplary embodiment of the present invention will be described with reference to FIG. 1. FIG. 1 is a timing chart showing a gas supply cycle according to the method of depositing the thin film according to the exemplary embodiment of the present invention.

Referring to FIG. 1, in the method of depositing the thin film according to the present exemplary embodiment, oxygen gas (O₂) and nitrogen gas (N₂) as reaction gases, and an inert purge gas (Ar) are successively supplied and a silicon source gas (Si source gas) and plasma are intermittently supplied to a plurality of reactors by using a deposition device including a plurality of reactors.

More specifically, the oxygen gas (O₂), the nitrogen gas (N₂), the inert purge gas (Ar) and the silicon source gas (Si source gas) are supplied for a first period t1. While supplying of the silicon source gas is stopped, the oxygen gas (O₂), the nitrogen gas (N₂) and the inert purge gas (Ar) are supplied for a second period t2. Plasma is supplied while the oxygen gas (O₂), the nitrogen gas (N₂) and the inert purge gas (Ar) are supplied for a third period t3. Then, while supplying of plasma is stopped, the oxygen gas (O₂), the nitrogen gas (N₂) and the inert purge gas (Ar) are supplied for a fourth period t4.

Like this, according to the method of depositing the thin film according to the present exemplary embodiment, the oxygen gas (O₂) and the nitrogen gas (N₂) are supplied as the reaction gases, and the inert purge gas (Ar) are successively supplied for the first period t1 to the fourth period t4. The silicon source gas is supplied for the first period t1. Plasma is supplied for the third period t3.

Herein, the silicon source gas may include at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DIPAS, SiH₃N(iPr)₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; TEOS, Si(OEt)₄; SiCl₄; HCD, Si₂Cl₆; MCS, SiH₃Cl; DCS, SiH₂Cl₂; 3DMAS, SiH(N(Me)₂)₃; BEMAS, SiH₂[N(Et)(Me)]₂; AHEAD, Si₂(NHEt)₆; TEAS, Si(NHEt)₄; and Si₃H₈.

The silicon source gas may comprise one or more of the following: SiI₄, HSiI₃, H₂SiI₂, H₃SiI, Si₂I₆, HSi₂I₅, H₂Si₂I₄, H₃Si₂I₃, H₄Si₂I₂, H₅Si₂I, Si₃I₈, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, HMe₂SiI, HMeSi₂I₄, HMe₂Si₂I₃, HMe₃Si₂I₂, HMe₄Si₂I, H₂MeSiI, H₂MeSi₂I₃, H₂Me₂Si₂I₂, H₂Me₃Si₂I, H₃MeSi₂I₂, H₃Me₂Si₂I, H₄MeSi₂I, EtSiI₃, Et₂SiI₂, Et₃SiI, EtSi₂I₅, Et₂Si₂I₄, Et₃Si₂I₃, Et₄Si₂I₂, Et₅Si₂I, HEtSiI₂, HEt₂SiI, HEtSi₂I₄, HEt₂Si₂I₃, HEt₃Si₂I₂, HEt₄Si₂I, H₂EtSiI, H₂EtSi₂I₃, H₂Et₂Si₂I₂, H₂Et₃Si₂I, H₃EtSi₂I₂, H₃Et₂Si₂I and H₄EtSi₂I.

The silicon source gas may comprise one or more of the following: EtMeSiI₂, Et₂MeSiI, EtMe₂SiI, EtMeSi₂I₄, Et₂MeSi₂I₃, EtMe₂Si₂I₃, Et₃MeSi₂I₂, Et₂Me₂Si₂I₂, EtMe₃Si₂I₂, Et₄MeSi₂I, Et₃Me₂Si₂I, Et₂Me₃Si₂I, EtMe₄Si₂I, HEtMeSiI, HEtMeSi₂I₃, HEt₂MeSi₂I₂, HEtMe₂Si₂I₂, HEt₃MeSi₂I, HEt₂Me₂Si₂I, HEtMe₃Si₂I, H₂EtMeSi₂I₂, H₂Et₂MeSi₂I, H₂EtMe₂Si₂I, H₃EtMeSi₂I.

The silicon source gas may comprise two, three, four, five, six, seven, eight, nine, ten, eleven, twelve, thirteen, fourteen, fifteen, sixteen, seventeen, eighteen, nineteen or more compounds selected from HSiI₃, H₂SiI₂, H₃SiI, H₂Si₂I₄, H₄Si₂I₂, H₅Si₂I, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, H₂Me₂Si₂I₂, EtSiI₃, Et₂SiI₂, Et₃SiI, Et₂Si₂I₄, Et₄Si₂I₂ and HEtSiI₂, including any combinations thereof.

The nitrogen gas may include at least one of N₂, NO, N₂O NO₂, N₂H₄, NH₃ and N₂/H₂ mixture. The oxygen gas may include at least one of O₂, CO, CO₂, N₂O and O₃ including an oxygen molecule, or a combination thereof.

The plasma may be supplied through in-situ plasma generated in a reaction space on a substrate on which the thin film is deposited, or remote plasma generated outside the reaction space may be transported and supplied to the reaction space.

Since oxygen and nitrogen have weak reactivity with the silicon source gas in an inactive state, a silicon oxynitride (SiON) film is not deposited for the first period t1 and the second period t2. The oxygen gas and the nitrogen gas supplied for the third period t3 for which plasma is supplied are activated, and react with the supplied silicon source gas to deposit the silicon oxynitride (SiON) film.

Gas supply cycles (x-cycle) of the first period t1, the second period t2, the third period t3, and the fourth period t4 are repeated as much as is desired to deposit the silicon oxynitride film having a desired thickness.

According to the method of depositing the thin film according to the exemplary embodiment of the present invention, plasma may be stably supplied by supplying the reaction gas and the source gas to each reactor of a multi-chamber deposition device in an inactive state before supplying plasma to each reactor and then supplying plasma to each reactor on a predetermined cycle of time. In general, if the reaction gas is supplied when plasma is supplied, a pressure fluctuation may occur in the reactor due to an inflow of a novel gas (reaction gas). Accordingly, an occurrence of plasma may become unstable. Accordingly, reproducibility of a deposition process is reduced during each reaction period. However, according to the method of depositing the thin film according to the exemplary embodiment of the present invention, plasma may be stably supplied to each reactor of a plurality of reactors and the silicon oxynitride film having a uniform characteristic and reproducibility may be deposited during each reaction period by supplying the reaction gas and the source gas in an inactive state to each reactor to stabilize pressure in the reactor before plasma is generated, and then supplying plasma on a predetermined cycle of time.

Like this, according to the method of depositing the thin film according to the exemplary embodiment of the present invention, unlike a known plasma enhanced chemical vapor deposition method (PECVD), process gases may be sequentially supplied to the reactor by using a plasma enhanced atomic layer deposition method (PEALD) and the reaction gas may be supplied in advance before plasma is supplied to minimize a pressure fluctuation in each reactor. Thereby, uniformity of the deposited thin film in each reactor may be improved among the reactors, and a thickness of the thin film may be precisely controlled. Accordingly, uniformity of the deposited thin film in each reactor may be improved in each reactor of the multi-chamber deposition device including a plurality of reactors to improve process reproducibility among reactors.

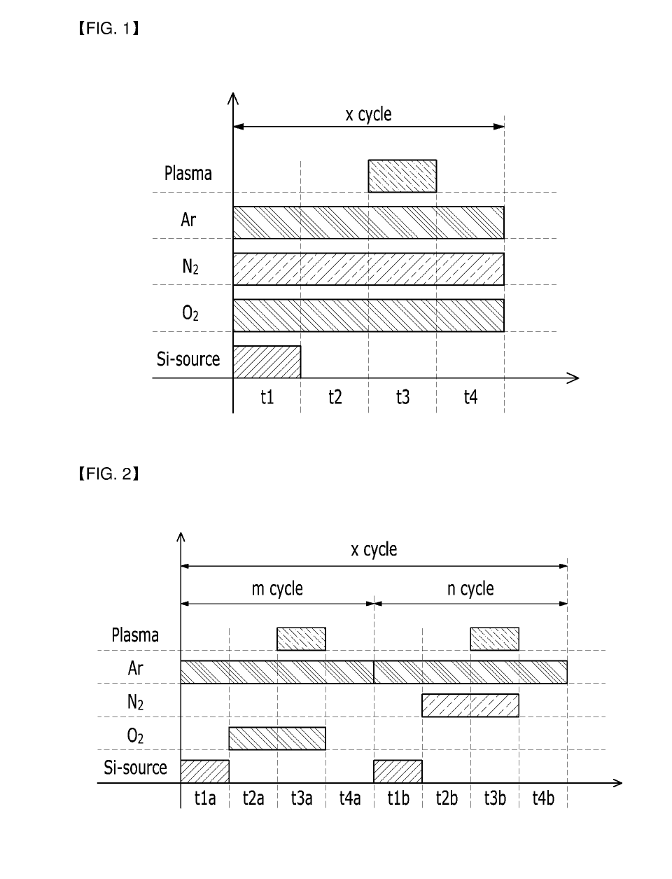

Then, a method of depositing a thin film according to another exemplary embodiment of the present invention will be described with reference to FIG. 2. FIG. 2 is a timing chart showing a gas supply cycle according to the method of depositing a thin film according to the exemplary embodiment of the present invention.

Referring to FIG. 2, in the method of depositing the thin film according to the present exemplary embodiment, a gas supply cycle (x cycle) including a first gas supply cycle (m cycle) and a second gas supply cycle (n cycle) is repeated to deposit the thin film.

The first gas supply cycle (m cycle) will be described. An inert purge gas (Ar) and a silicon source gas (Si source gas) are supplied for a first sub-period t1a. The inert purge gas (Ar) and oxygen gas (O₂) are supplied for a second sub-period t2a. The inert purge gas (Ar), the oxygen gas (O₂), and plasma are supplied for a third sub-period t3a. The inert purge gas (Ar) is supplied for a fourth sub-period t4a. A silicon oxide (SiO₂) film having a desired thickness may be deposited by repeating the first gas supply cycle (m cycle).

The second gas supply cycle (n cycle) will be described. The inert purge gas (Ar) and the silicon source gas (Si source gas) are supplied for a fifth sub-period t1b. The inert purge gas (Ar) and nitrogen gas (N₂) are supplied for a second sub-period t2b. The inert purge gas (Ar), the nitrogen gas (N₂), and plasma are supplied for a third sub-period t3b. The inert purge gas (Ar) is supplied for a fourth sub-period t4b. A silicon nitride (SiN) film having a desired thickness may be deposited by repeating the second gas supply cycle (n cycle).

Herein, the silicon source gas may include at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DIPAS, SiH₃N(iPr)₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; TEOS, Si(OEt)₄; SiCl₄; HCD, Si₂Cl₆; MCS, SiH₃Cl; DCS, SiH₂Cl₂; 3DMAS, SiH(N(Me)₂)₃; BEMAS, SiH₂[N(Et)(Me)]₂; AHEAD, Si₂(NHEt)₆; TEAS, Si(NHEt)₄; and Si₃H₈.

The silicon source gas may comprise one or more of the following: SiI₄, HSiI₃, H₂SiI₂, H₃SiI, Si₂I₆, HSi₂I₅, H₂Si₂I₄, H₃Si₂I₃, H₄Si₂I₂, H₅Si₂I, Si₃I₈, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, HMe₂SiI, HMeSi₂I₄, HMe₂Si₂I₃, HMe₃Si₂I₂, HMe₄Si₂I, H₂MeSiI, H₂MeSi₂I₃, H₂Me₂Si₂I₂, H₂Me₃Si₂I, H₃MeSi₂I₂, H₃Me₂Si₂I, H₄MeSi₂I, EtSiI₃, Et₂SiI₂, Et₃SiI, EtSi₂I₅, Et₂Si₂I₄, Et₃Si₂I₃, Et₄Si₂I₂, Et₅Si₂I, HEtSiI₂, HEt₂SiI, HEtSi₂I₄, HEt₂Si₂I₃, HEt₃Si₂I₂, HEt₄Si₂I, H₂EtSiI, H₂EtSi₂I₃, H₂Et₂Si₂I₂, H₂Et₃Si₂I, H₃EtSi₂I₂, H₃Et₂Si₂I and H₄EtSi₂I.

The silicon source gas may comprise one or more of the following: EtMeSiI₂, Et₂MeSiI, EtMe₂SiI, EtMeSi₂I₄, Et₂MeSi₂I₃, EtMe₂Si₂I₃, Et₃MeSi₂I₂, Et₂Me₂Si₂I₂, EtMe₃Si₂I₂, Et₄MeSi₂I, Et₃Me₂Si₂I, Et₂Me₃Si₂I, EtMe₄Si₂I, HEtMeSiI, HEtMeSi₂I₃, HEt₂MeSi₂I₂, HEtMe₂Si₂I₂, HEt₃MeSi₂I, HEt₂Me₂Si₂I, HEtMe₃Si₂I, H₂EtMeSi₂I₂, H₂Et₂MeSi₂I, H₂EtMe₂Si₂I, H₃EtMeSi₂I.

The silicon source gas may comprise two, three, four, five, six, seven, eight, nine, ten, eleven, twelve, thirteen, fourteen, fifteen, sixteen, seventeen, eighteen, nineteen or more compounds selected from HSiI₃, H₂SiI₂, H₃SiI, H₂Si₂I₄, H₄Si₂I₂, H₅Si₂I, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, H₂Me₂Si₂I₂, EtSiI₃, Et₂SiI₂, Et₃SiI, Et₂Si₂I₄, Et₄Si₂I₂ and HEtSiI₂, including any combinations thereof.

The nitrogen gas may include at least one of N₂, NO, N₂O NO₂, N₂H₄, NH₃ and N₂/H₂ mixture. The oxygen gas may include at least one of O₂, CO, CO₂, N₂O and O₃

The plasma may be supplied through in-situ plasma generated in a reaction space on a substrate on which the thin film is deposited, or remote plasma generated outside the reaction space may be transported and supplied to the reaction space.

A silicon oxynitride (SiON) film having a desired thickness may be deposited by repeating the first gas supply cycle (m cycle) and the second gas supply cycle (n cycle). In this case, the first gas supply cycle (m cycle) and the second gas supply cycle (n cycle) may be alternately repeated, or repeating of the first gas supply cycle (m cycle) for first plural times and repeating of the second gas supply cycle (n cycle) for second plural times may be alternately repeated. Herein, the first plural times and the second plural times may be the same as or different from each other.

Like this, an oxygen content and a nitrogen content in the silicon oxynitride (SiON) film may be adjusted by adjusting the number of repetition of the first gas supply cycle (m cycle) and the second gas supply cycle (n cycle). Accordingly, thin films having various compositions may be deposited according to the application purpose of the thin film.

According to the method of depositing the thin film according to the exemplary embodiment of the present invention, before plasma is supplied to each reactor of a multi-chamber deposition device, the source gas and a reaction gas in an inactive state may be supplied to each reactor and plasma may be then supplied on a predetermined cycle of time to minimize a pressure fluctuation in the reactor and stably supply plasma to each reactor. Therefore, thin film can be deposited with reproducibility among the reactors. Further, the oxygen content and the nitrogen content in the silicon oxynitride film may be adjusted by appropriately adjusting the number of repetition of the first supply cycle and the second supply cycle.

Like this, according to the method of depositing the thin film according to the exemplary embodiment of the present invention, unlike a known plasma enhanced chemical vapor deposition method (PECVD), process gases may be sequentially supplied to the reactor by using a plasma enhanced atomic layer deposition method (PEALD) and the reaction gas may be supplied in advance before plasma is supplied to minimize a pressure fluctuation in each reactor. Thereby, uniformity of the thin film may be improved among the reactors, and a thickness of the thin film may be precisely controlled. Accordingly, uniformity and reproducibility of the deposited thin film may be improved among the reactors of the multi-chamber deposition device including a plurality of reactors.

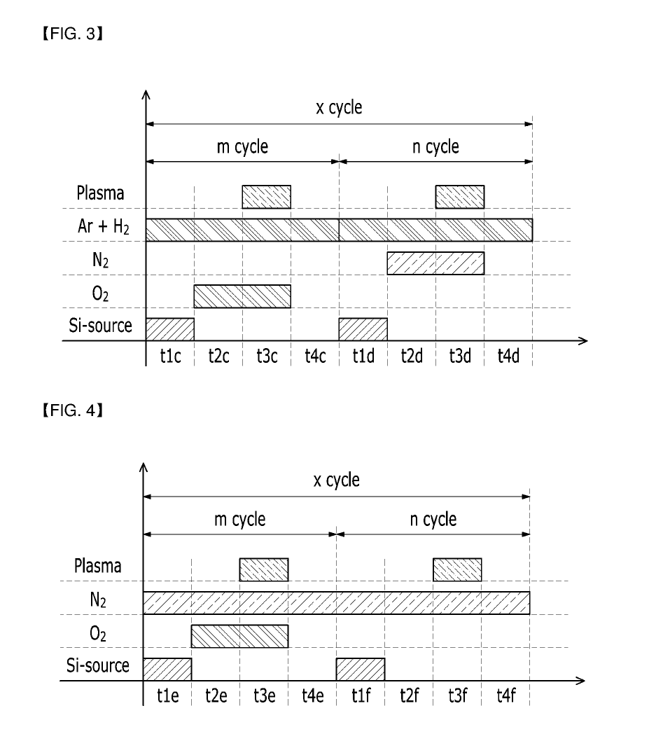

Then, a method of depositing a thin film according to another exemplary embodiment of the present invention will be described with reference to FIG. 3. FIG. 3 is a timing chart showing a gas supply cycle according to the method of depositing a thin film according to the exemplary embodiment of the present invention.

Referring to FIG. 3, the gas supply cycle according to the method of depositing the thin film according to the present exemplary embodiment is similar to the gas supply cycle according to the exemplary embodiment described with reference to FIG. 2.

A first gas supply cycle (m cycle) will be described. While an inert purge gas (Ar) and a hydrogen (H₂) gas are supplied, a silicon source gas (Si source gas) is supplied for a first sub-period t1c. While the inert purge gas (Ar) and the hydrogen (H₂) gas are supplied, oxygen gas (O₂) is supplied for a second sub-period t2c. While the inert purge gas (Ar) and the hydrogen (H₂) gas are supplied, the oxygen gas (O₂) and plasma are supplied for a third sub-period t3c. The inert purge gas (Ar) and the hydrogen (H₂) gas are supplied for a fourth sub-period t4c. A silicon oxide (SiO₂) film having a desired thickness may be deposited by repeating the first gas supply cycle (m cycle).

A second gas supply cycle (n cycle) will be described. While the inert purge gas (Ar) and the hydrogen (H₂) gas are supplied, the silicon source gas (Si source gas) is supplied for a fifth sub-period t1d. While the inert purge gas (Ar) and the hydrogen (H₂) gas are supplied, nitrogen gas (N₂) is supplied for a second sub-period t2d. While the inert purge gas (Ar) and the hydrogen (H₂) gas are supplied, the nitrogen gas (N₂) and plasma are supplied for a third sub-period t3d. The inert purge gas (Ar) and the hydrogen (H₂) gas are supplied for a fourth sub-period t4d. A silicon nitride (SiN) film having a desired thickness may be deposited by repeating the second gas supply cycle (n cycle).

Like this, according to the gas supply cycle of the method of depositing thin film according to the present exemplary embodiment, the inert purge gas (Ar) and the hydrogen gas (H₂) are supplied together. Separation of a ligand of a silicon precursor (Si precursor) may be more easily performed and a reaction between silicon (Si) and nitrogen (N) may be promoted by supplying the hydrogen gas (H₂) together. That is, the ligand is separated from a silicon (Si) element and bonded to a hydrogen element due to hydrogen plasma to be exhausted as a byproduct. Thereby, bonding of silicon (Si) and nitrogen (N) is more easily performed. Accordingly, a characteristic of the silicon nitride (SiN) film may be adjusted by adjusting an amount of supplied hydrogen.

Herein, the silicon source gas may include at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DIPAS, SiH₃N(iPr)₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; TEOS, Si(OEt)₄; SiCl₄; HCD, Si₂Cl₆; MCS, SiH₃Cl; DCS, SiH₂Cl₂; 3DMAS, SiH(N(Me)₂)₃; BEMAS, SiH₂[N(Et)(Me)]₂; AHEAD, Si₂(NHEt)₆; TEAS, Si(NHEt)₄; and Si₃H₈.

The silicon source gas may comprise one or more of the following: SiI₄, HSiI₃, H₂SiI₂, H₃SiI, Si₂I₆, HSi₂I₅, H₂Si₂I₄, H₃Si₂I₃, H₄Si₂I₂, H₅Si₂I, Si₃I₈, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, HMe₂SiI, HMeSi₂I₄, HMe₂Si₂I₃, HMe₃Si₂I₂, HMe₄Si₂I, H₂MeSiI, H₂MeSi₂I₃, H₂Me₂Si₂I₂, H₂Me₃Si₂I, H₃MeSi₂I₂, H₃Me₂Si₂I, H₄MeSi₂I, EtSiI₃, Et₂SiI₂, Et₃SiI, EtSi₂I₅, Et₂Si₂I₄, Et₃Si₂I₃, Et₄Si₂I₂, Et₅Si₂I, HEtSiI₂, HEt₂SiI, HEtSi₂I₄, HEt₂Si₂I₃, HEt₃Si₂I₂, HEt₄Si₂I, H₂EtSiI, H₂EtSi₂I₃, H₂Et₂Si₂I₂, H₂Et₃Si₂I, H₃EtSi₂I₂, H₃Et₂Si₂I and H₄EtSi₂I.

The silicon source gas may comprise one or more of the following: EtMeSiI₂, Et₂MeSiI, EtMe₂SiI, EtMeSi₂I₄, Et₂MeSi₂I₃, EtMe₂Si₂I₃, Et₃MeSi₂I₂, Et₂Me₂Si₂I₂, EtMe₃Si₂I₂, Et₄MeSi₂I, Et₃Me₂Si₂I, Et₂Me₃Si₂I, EtMe₄Si₂I, HEtMeSiI, HEtMeSi₂I₃, HEt₂MeSi₂I₂, HEtMe₂Si₂I₂, HEt₃MeSi₂I, HEt₂Me₂Si₂I, HEtMe₃Si₂I, H₂EtMeSi₂I₂, H₂Et₂MeSi₂I, H₂EtMe₂Si₂I, H₃EtMeSi₂I.

The silicon source gas may comprise two, three, four, five, six, seven, eight, nine, ten, eleven, twelve, thirteen, fourteen, fifteen, sixteen, seventeen, eighteen, nineteen or more compounds selected from HSiI₃, H₂SiI₂, H₃SiI, H₂Si₂I₄, H₄Si₂I₂, H₅Si₂I, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, H₂Me₂Si₂I₂, EtSiI₃, Et₂SiI₂, Et₃SiI, Et₂Si₂I₄, Et₄Si₂I₂ and HEtSiI₂, including any combinations thereof.

The nitrogen gas may include at least one of N₂, NO, N₂O NO₂, N₂H₄, NH₃ and N₂/H₂ mixture. The oxygen gas may include at least one of O₂, CO, CO₂, N₂O and O₃

The plasma may be supplied through in-situ plasma generated in a reaction space on a substrate on which the thin film is deposited, or remote plasma generated outside the reaction space may be transported and supplied to the reaction space.

A silicon oxynitride (SiON) film having a desired thickness may be deposited by repeating the first gas supply cycle (m cycle) and the second gas supply cycle (n cycle). In this case, the first gas supply cycle (m cycle) and the second gas supply cycle (n cycle) may be alternately repeated, or repeating of the first gas supply cycle (m cycle) for first plural times and repeating of the second gas supply cycle (n cycle) for second plural times may be alternately repeated. Herein, the first plural times and the second plural times may be the same as or different from each other.

Like this, an oxygen content and a nitrogen content in the silicon oxynitride (SiON) film may be adjusted by adjusting the number of repetition of the first gas supply cycle (m cycle) and the second gas supply cycle (n cycle). Accordingly, thin films having various compositions may be deposited according to the application purpose of the thin film.

According to the method of depositing thin film according to the exemplary embodiment of the present invention, the source gas and a reaction gas in an inactive state may be supplied to each reactor before plasma is supplied to each reactor of a multi-chamber deposition device including a plurality of reactors and plasma may be then supplied on a predetermined cycle of time to minimize a pressure fluctuation in the reactor and stably supply plasma to each reactor. Therefore, thin film can be deposited on a substrate in each reactor with reproducibility among the reactors. Further, the oxygen content and the nitrogen content in the silicon oxynitride film may be adjusted by appropriately adjusting the number of repetition of the first supply cycle and the second supply cycle.

Like this, according to the method of depositing the thin film according to the exemplary embodiment of the present invention, unlike a known plasma enhanced chemical vapor deposition method (PECVD), process gases may be sequentially supplied to the reactor by using a plasma enhanced atomic layer deposition method (PEALD) and the reaction gas may be supplied in advance before plasma is supplied to minimize a pressure fluctuation in each reactor. Thereby, uniformity of the thin film may be increased among the reactors, and a thickness of the thin film may be precisely controlled. Accordingly, uniformity of the deposited thin film may be improved in each reactor of the multi-chamber deposition device including a plurality of reactors to improve process reproducibility among reactors.

Then, a method of depositing a thin film according to another exemplary embodiment of the present invention will be described with reference to FIG. 4. FIG. 4 is a timing chart showing a gas supply cycle according to the method of depositing a thin film according to the exemplary embodiment of the present invention.

A first gas supply cycle (m cycle) will be described. While nitrogen gas (N₂) is supplied, a silicon source gas (Si source gas) is supplied for a first sub-period t1e. While the nitrogen gas (N₂) is supplied, oxygen gas (O₂) is supplied for a second sub-period t2e. While the nitrogen gas (N₂) is supplied, the oxygen gas (O₂) and plasma are supplied for a third sub-period t3e. The nitrogen gas (N₂) is supplied for a fourth sub-period t4e. A silicon oxide (SiO₂) film having a desired thickness may be deposited by repeating the first gas supply cycle (m cycle).

A second gas supply cycle (n cycle) will be described. While the nitrogen gas (N₂) is supplied, the silicon source gas (Si source gas) is supplied for a fifth sub-period t1f. The nitrogen gas (N₂) is supplied for a second sub-period t2f. The nitrogen gas (N₂) and plasma are supplied for a third sub-period t3f. The nitrogen gas (N₂) is supplied for a fourth sub-period t4f. A silicon nitride (SiN) film having a desired thickness may be deposited by repeating the second gas supply cycle (n cycle).

Like this, according to the gas supply cycle of the method of depositing the thin film according to the present exemplary embodiment, the nitrogen gas (N₂) in an inactive state is used as a purge gas while an additional inert purge gas is not supplied. The nitrogen gas (N₂) in an inactive state is not reacted with the silicon source gas (Si source gas). The nitrogen gas (N₂) activated by supplying plasma reacts with the silicon source gas (Si source gas). Accordingly, the nitrogen gas (N₂) activated by supplying plasma acts as a reaction gas.

Herein, the silicon source gas may include at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DIPAS, SiH₃N(iPr)₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; TEOS, Si(OEt)₄; SiCl₄; HCD, Si₂Cl₆; MCS, SiH₃Cl; DCS, SiH₂Cl₂; 3DMAS, SiH(N(Me)₂)₃; BEMAS, SiH₂[N(Et)(Me)]₂; AHEAD, Si₂(NHEt)₆; TEAS, Si(NHEt)₄; and Si₃H₈.

The silicon source gas may comprise one or more of the following: SiI₄, HSiI₃, H₂SiI₂, H₃SiI, Si₂I₆, HSi₂I₅, H₂Si₂I₄, H₃Si₂I₃, H₄Si₂I₂, H₅Si₂I, Si₃I₈, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, HMe₂SiI, HMeSi₂I₄, HMe₂Si₂I₃, HMe₃Si₂I₂, HMe₄Si₂I, H₂MeSiI, H₂MeSi₂I₃, H₂Me₂Si₂I₂, H₂Me₃Si₂I, H₃MeSi₂I₂, H₃Me₂Si₂I, H₄MeSi₂I, EtSiI₃, Et₂SiI₂, Et₃SiI, EtSi₂I₅, Et₂Si₂I₄, Et₃Si₂I₃, Et₄Si₂I₂, Et₅Si₂I, HEtSiI₂, HEt₂SiI, HEtSi₂I₄, HEt₂Si₂I₃, HEt₃Si₂I₂, HEt₄Si₂I, H₂EtSiI, H₂EtSi₂I₃, H₂Et₂Si₂I₂, H₂Et₃Si₂I, H₃EtSi₂I₂, H₃Et₂Si₂I and H₄EtSi₂I.

The silicon source gas may comprise one or more of the following: EtMeSiI₂, Et₂MeSiI, EtMe₂SiI, EtMeSi₂I₄, Et₂MeSi₂I₃, EtMe₂Si₂I₃, Et₃MeSi₂I₂, Et₂Me₂Si₂I₂, EtMe₃Si₂I₂, Et₄MeSi₂I, Et₃Me₂Si₂I, Et₂Me₃Si₂I, EtMe₄Si₂I, HEtMeSiI, HEtMeSi₂I₃, HEt₂MeSi₂I₂, HEtMe₂Si₂I₂, HEt₃MeSi₂I, HEt₂Me₂Si₂I, HEtMe₃Si₂I, H₂EtMeSi₂I₂, H₂Et₂MeSi₂I, H₂EtMe₂Si₂I, H₃EtMeSi₂I.

The silicon source gas may comprise two, three, four, five, six, seven, eight, nine, ten, eleven, twelve, thirteen, fourteen, fifteen, sixteen, seventeen, eighteen, nineteen or more compounds selected from HSiI₃, H₂SiI₂, H₃SiI, H₂Si₂I₄, H₄Si₂I₂, H₅Si₂I, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, H₂Me₂Si₂I₂, EtSiI₃, Et₂SiI₂, Et₃SiI, Et₂Si₂I₄, Et₄Si₂I₂ and HEtSiI₂, including any combinations thereof.

The nitrogen gas may include at least one of N₂, NO, N₂O NO₂, N₂H₄, NH₃ and N₂/H₂ mixture. The oxygen gas may include at least one of O₂, CO, CO₂, N₂O and O₃

The plasma may be supplied through in-situ plasma generated in a reaction space on a substrate on which the thin film is deposited, or remote plasma generated outside the reaction space may be transported and supplied to the reaction space.

A silicon oxynitride (SiON) film having a desired thickness may be deposited by repeating the first gas supply cycle (m cycle) and the second gas supply cycle (n cycle). In this case, the first gas supply cycle (m cycle) and the second gas supply cycle (n cycle) may be alternately repeated, or repeating of the first gas supply cycle (m cycle) for first plural times and repeating of the second gas supply cycle (n cycle) for second plural times may be alternately repeated. Herein, the first plural times and the second plural times may be the same as or different from each other.

Like this, an oxygen content and a nitrogen content in the silicon oxynitride (SiON) film may be adjusted by adjusting the number of repetition of the first gas supply cycle (m cycle) and the second gas supply cycle (n cycle). Accordingly, thin films having various compositions may be deposited according to the application purpose of the thin film.

According to the method of depositing the thin film according to the exemplary embodiment of the present invention, the source gas and the reaction gas in an inactive state may be supplied to each reactor before plasma is supplied to each reactor of a multi-chamber deposition device, and plasma may be then supplied on a predetermined cycle of time to minimize a pressure fluctuation in the reactor and stably supply plasma to each reactor. Therefore, thin film can be deposited on substrate in each reactor with reproducibility among the reactors. Further, the oxygen content and the nitrogen content in the silicon oxynitride film may be adjusted by appropriately adjusting the number of repetition of the first supply cycle and the second supply cycle.

Like this, according to the method of depositing thin film according to the exemplary embodiment of the present invention, unlike a known plasma enhanced chemical vapor deposition method (PECVD), process gases may be sequentially supplied to the reactor by using a plasma enhanced atomic layer deposition method (PEALD) and the reaction gas may be supplied in advance before plasma is supplied to minimize a pressure fluctuation in each reactor. Thereby, uniformity of the thin film may be improved among the reactors, and a thickness of the thin film may be precisely controlled. Accordingly, uniformity of the deposited thin film may be improved in each reactor of the multi-chamber deposition device including a plurality of reactors to improve process reproducibility among reactors.

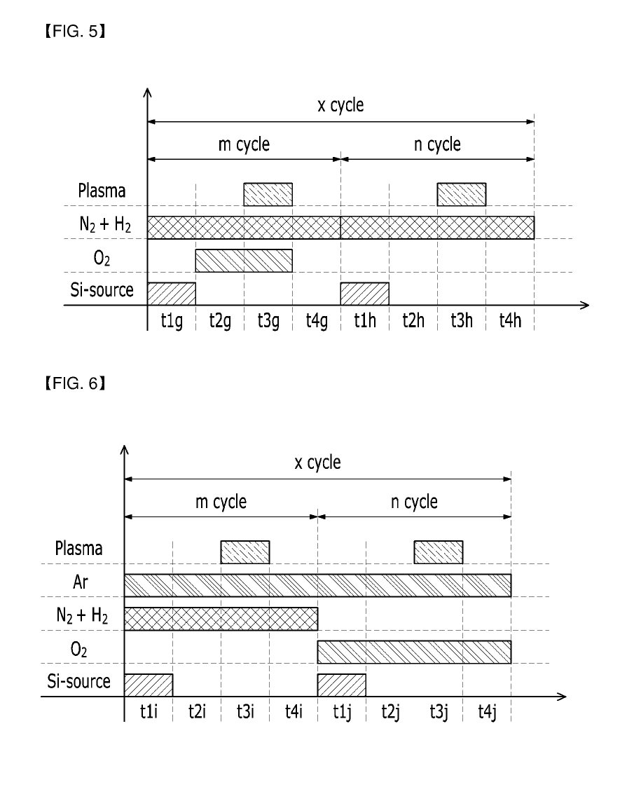

Then, a method of depositing a thin film according to another exemplary embodiment of the present invention will be described with reference to FIG. 5. FIG. 5 is a timing chart showing a gas supply cycle according to the method of depositing the thin film according to the exemplary embodiment of the present invention.

A first gas supply cycle (m cycle) will be described. While nitrogen gas (N₂) and hydrogen (H₂) gas are supplied, a silicon source gas (Si source gas) is supplied for a first sub-period t1g. While the nitrogen gas (N₂) and the hydrogen (H₂) gas are supplied, oxygen gas (O₂) is further supplied for a second sub-period t2g. While the nitrogen gas (N₂) and the hydrogen (H₂) gas are supplied, the oxygen gas (O₂) and plasma are supplied for a third sub-period t3g. The nitrogen gas (N₂) and the hydrogen (H₂) gas are supplied for a fourth sub-period t4g. A silicon oxide (SiO₂) film having a desired thickness may be deposited by repeating the first gas supply cycle (m cycle).

A second gas supply cycle (n cycle) will be described. While the nitrogen gas (N₂) and the hydrogen (H₂) gas are supplied, the silicon source gas (Si source gas) is supplied for a fifth sub-period t1h. The nitrogen gas (N₂) and the hydrogen (H₂) gas are supplied for a second sub-period t2h. While the nitrogen gas (N₂) and the hydrogen (H₂) gas are supplied, plasma is supplied for a third sub-period t3h. The nitrogen gas (N₂) and the hydrogen (H₂) gas are supplied for a fourth sub-period t4h. A silicon nitride (SiN) film having a desired thickness may be deposited by repeating the second gas supply cycle (n cycle).

Like this, according to the gas supply cycle of the method of depositing a thin film according to the present exemplary embodiment, the nitrogen gas (N₂) in an inactive state is used as a purge gas while an additional inert purge gas is not supplied. The nitrogen gas (N₂) in an inactive state is not reacted with the silicon source gas (Si source gas). The nitrogen gas (N₂) activated by supplying plasma reacts with the silicon source gas (Si source gas). Accordingly, the nitrogen gas (N₂) activated by supplying plasma acts as a reaction gas.

Further, the nitrogen gas (N₂) and the hydrogen gas (H₂) are supplied together. Separation of a ligand of a silicon precursor (Si precursor) may be more easily performed and a reaction between silicon (Si) and nitrogen (N) may be promoted by supplying the hydrogen gas (H₂) together. That is, the ligand is separated from a silicon (Si) element and bonded to a hydrogen element due to hydrogen plasma to be exhausted as a byproduct. Thereby, bonding of silicon (Si) and nitrogen (N) is more easily performed. Accordingly, a characteristic of the silicon nitride (SiN) film may be adjusted by adjusting an amount of supplied hydrogen.

Herein, the silicon source gas may include at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DIPAS, SiH₃N(iPr)₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; TEOS, Si(OEt)₄; SiCl₄; HCD, Si₂Cl₆; MCS, SiH₃Cl; DCS, SiH₂Cl₂; 3DMAS, SiH(N(Me)₂)₃; BEMAS, SiH₂[N(Et)(Me)]₂; AHEAD, Si₂(NHEt)₆; TEAS, Si(NHEt)₄; and Si₃H₈.

The silicon source gas may comprise one or more of the following: SiI₄, HSiI₃, H₂SiI₂, H₃SiI, Si₂I₆, HSi₂I₅, H₂Si₂I₄, H₃Si₂I₃, H₄Si₂I₂, H₅Si₂I, Si₃I₈, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, HMe₂SiI, HMeSi₂I₄, HMe₂Si₂I₃, HMe₃Si₂I₂, HMe₄Si₂I, H₂MeSiI, H₂MeSi₂I₃, H₂Me₂Si₂I₂, H₂Me₃Si₂I, H₃MeSi₂I₂, H₃Me₂Si₂I, H₄MeSi₂I, EtSiI₃, Et₂SiI₂, Et₃SiI, EtSi₂I₅, Et₂Si₂I₄, Et₃Si₂I₃, Et₄Si₂I₂, Et₅Si₂I, HEtSiI₂, HEt₂SiI, HEtSi₂I₄, HEt₂Si₂I₃, HEt₃Si₂I₂, HEt₄Si₂I, H₂EtSiI, H₂EtSi₂I₃, H₂Et₂Si₂I₂, H₂Et₃Si₂I, H₃EtSi₂I₂, H₃Et₂Si₂I and H₄EtSi₂I.

The silicon source gas may comprise one or more of the following: EtMeSiI₂, Et₂MeSiI, EtMe₂SiI, EtMeSi₂I₄, Et₂MeSi₂I₃, EtMe₂Si₂I₃, Et₃MeSi₂I₂, Et₂Me₂Si₂I₂, EtMe₃Si₂I₂, Et₄MeSi₂I, Et₃Me₂Si₂I, Et₂Me₃Si₂I, EtMe₄Si₂I, HEtMeSiI, HEtMeSi₂I₃, HEt₂MeSi₂I₂, HEtMe₂Si₂I₂, HEt₃MeSi₂I, HEt₂Me₂Si₂I, HEtMe₃Si₂I, H₂EtMeSi₂I₂, H₂Et₂MeSi₂I, H₂EtMe₂Si₂I, H₃EtMeSi₂I.

The silicon source gas may comprise two, three, four, five, six, seven, eight, nine, ten, eleven, twelve, thirteen, fourteen, fifteen, sixteen, seventeen, eighteen, nineteen or more compounds selected from HSiI₃, H₂SiI₂, H₃SiI, H₂Si₂I₄, H₄Si₂I₂, H₅Si₂I, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, H₂Me₂Si₂I₂, EtSiI₃, Et₂SiI₂, Et₃SiI, Et₂Si₂I₄, Et₄Si₂I₂ and HEtSiI₂, including any combinations thereof.

The nitrogen gas may include at least one of N₂, NO, N₂O NO₂, N₂H₄, NH₃ and N₂/H₂ mixture. The oxygen gas may include at least one of O₂, CO, CO₂, N₂O and O₃

The plasma may be supplied through in-situ plasma generated in a reaction space on a substrate on which the thin film is deposited, or remote plasma generated outside the reaction space and supplied to the reaction space.

A silicon oxynitride (SiON) film having a desired thickness may be deposited by repeating the first gas supply cycle (m cycle) and the second gas supply cycle (n cycle). In this case, the first gas supply cycle (m cycle) and the second gas supply cycle (n cycle) may be alternately repeated, or repeating of the first gas supply cycle (m cycle) for first plural times and repeating of the second gas supply cycle (n cycle) for second plural times may be alternately repeated. Herein, the first plural times and the second plural times may be the same as or different from each other.

Like this, an oxygen content and a nitrogen content in the silicon oxynitride (SiON) film may be adjusted by adjusting the number of repetition of the first gas supply cycle (m cycle) and the second gas supply cycle (n cycle). Accordingly, thin films having various compositions may be deposited according to the application purpose of the thin film.

According to the method of depositing the thin film according to the exemplary embodiment of the present invention, the source gas and the reaction gas in an inactive state may be supplied to each reactor before plasma is supplied to each reactor of a multi-chamber deposition device, and plasma may be then supplied on a predetermined cycle of time to minimize a pressure fluctuation in the reactor and stably supply plasma to each reactor. Therefore, thin film can be deposited on a substrate in each reactor with reproducibility among the reactors. Further, the oxygen content and the nitrogen content in the silicon oxynitride film may be adjusted by appropriately adjusting the number of repetition of the first supply cycle and the second supply cycle.

Like this, according to the method of depositing the thin film according to the exemplary embodiment of the present invention, unlike a known plasma enhanced chemical vapor deposition method (PECVD), process gases may be sequentially supplied to the reactor by using a plasma enhanced atomic layer deposition method (PEALD) and the reaction gas may be supplied in advance before plasma is supplied to minimize a pressure fluctuation in each reactor. Thereby, uniformity of the thin film may be improved among the reactors, and a thickness of the thin film may be precisely controlled. Accordingly, uniformity of the deposited thin film may be improved in each chamber of the multi-chamber deposition device including a plurality of reactors to improve process reproducibility among reactors.

Then, a method of depositing a thin film according to another exemplary embodiment of the present invention will be described with reference to FIGS. 6˜8. FIGS. 6˜8 are timing charts showing a gas supply cycle to deposit a thin film according to exemplary embodiments of the present invention.

A first gas supply cycle (m cycle) will be described. While nitrogen gas (N₂), hydrogen gas (H₂) and argon (Ar) gas are supplied, a silicon source gas (Si source gas) is supplied for a first sub-period t1i. For a second sub-period t2i, the nitrogen gas (N₂), hydrogen gas (H₂) and argon (Ar) gas are continuously supplied but the silicon source gas (Si source gas) is no more supplied. While the nitrogen gas (N₂), hydrogen gas (H₂) and argon (Ar) gas are supplied, plasma is supplied for a third sub-period t3i. The nitrogen gas (N₂), hydrogen gas (H₂) and argon (Ar) gas are continuously supplied but the plasma is no more supplied for a fourth sub-period t4i. A silicon nitride (SiN) film having a desired thickness may be deposited by repeating the first gas supply cycle (m cycle).

A second gas supply cycle (n cycle) will be described. While the oxygen gas (O₂) and argon (Ar) gas are supplied, the silicon source gas (Si source gas) is supplied for a fifth sub-period t1j. For a sixth sub-period t2j, the oxygen gas (O₂) and argon (Ar) gas are continuously supplied but the silicon source gas (Si source gas) is no more supplied. While the oxygen gas (O₂) and argon (Ar) gas are supplied, the plasma is supplied for a seventh sub-period t3j. The oxygen gas (O₂) and argon (Ar) gas are continuously supplied but the plasma is no more supplied for a eighth sub-period t4j. A silicon oxide (SiO) film having a desired thickness may be deposited by repeating the second gas supply cycle (n cycle).

Like this, according to the gas supply cycle to deposit a thin film according to the present exemplary embodiment, the argon gas (Ar), the nitrogen gas (N₂) hydrogen gas (H₂) and oxygen gas (O₂) in an inactive state are used as a purge gas. Those gases (Ar, N₂, H₂, O₂) in an inactive state do not react with the silicon source gas (Si source gas). The nitrogen gas (N₂), hydrogen gas (H₂) and oxygen gas (O₂) are activated by supplying plasma to react with the silicon source gas (Si source gas). Accordingly, the nitrogen gas (N₂), hydrogen gas (H₂) and oxygen gas (O₂) are activated by supplying plasma to work as a reaction gas.

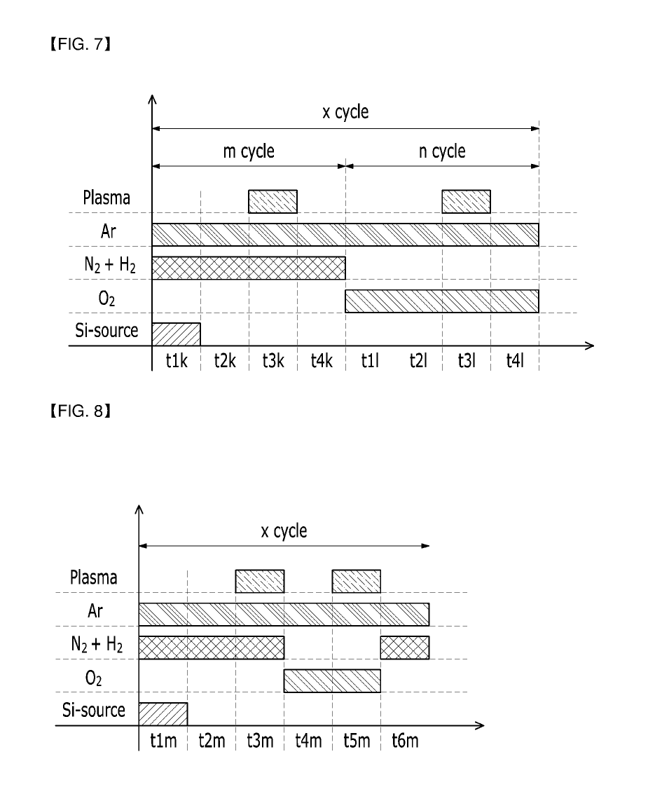

As another embodiment, in the method of FIG. 7, there is no silicon source gas (Si source gas) feed in the second gas supply cycle (n cycle) compared with the method of FIG. 6. And FIG. 8 illustrates another embodiment where, the sequence of FIG. 7 is simplified. In other words, the fourth sub-period t4k and the fifth sub-period t1l of FIG. 7 were omitted.

Herein, the silicon source gas may include at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DIPAS, SiH₃N(iPr)₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; TEOS, Si(OEt)₄; SiCl₄; HCD, Si₂Cl₆; MCS, SiH₃Cl; DCS, SiH₂Cl₂; 3DMAS, SiH(N(Me)₂)₃; BEMAS, SiH₂[N(Et)(Me)]₂; AHEAD, Si₂(NHEt)₆; TEAS, Si(NHEt)₄; and Si₃H₈.

The silicon source gas may comprise one or more of the following: SiI₄, HSiI₃, H₂SiI₂, H₃SiI, Si₂I₆, HSi₂I₅, H₂Si₂I₄, H₃Si₂I₃, H₄Si₂I₂, H₅Si₂I, Si₃I₈, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, HMe₂SiI, HMeSi₂I₄, HMe₂Si₂I₃, HMe₃Si₂I₂, HMe₄Si₂I, H₂MeSiI, H₂MeSi₂I₃, H₂Me₂Si₂I₂, H₂Me₃Si₂I, H₃MeSi₂I₂, H₃Me₂Si₂I, H₄MeSi₂I, EtSiI₃, Et₂SiI₂, Et₃SiI, EtSi₂I₅, Et₂Si₂I₄, Et₃Si₂I₃, Et₄Si₂I₂, Et₅Si₂I, HEtSiI₂, HEt₂SiI, HEtSi₂I₄, HEt₂Si₂I₃, HEt₃Si₂I₂, HEt₄Si₂I, H₂EtSiI, H₂EtSi₂I₃, H₂Et₂Si₂I₂, H₂Et₃Si₂I, H₃EtSi₂I₂, H₃Et₂Si₂I and H₄EtSi₂I.

The silicon source gas may comprise one or more of the following: EtMeSiI₂, Et₂MeSiI, EtMe₂SiI, EtMeSi₂I₄, Et₂MeSi₂I₃, EtMe₂Si₂I₃, Et₃MeSi₂I₂, Et₂Me₂Si₂I₂, EtMe₃Si₂I₂, Et₄MeSi₂I, Et₃Me₂Si₂I, Et₂Me₃Si₂I, EtMe₄Si₂I, HEtMeSiI, HEtMeSi₂I₃, HEt₂MeSi₂I₂, HEtMe₂Si₂I₂, HEt₃MeSi₂I, HEt₂Me₂Si₂I, HEtMe₃Si₂I, H₂EtMeSi₂I₂, H₂Et₂MeSi₂I, H₂EtMe₂Si₂I, H₃EtMeSi₂I.

The silicon source gas may comprise two, three, four, five, six, seven, eight, nine, ten, eleven, twelve, thirteen, fourteen, fifteen, sixteen, seventeen, eighteen, nineteen or more compounds selected from HSiI₃, H₂SiI₂, H₃SiI, H₂Si₂I₄, H₄Si₂I₂, H₅Si₂I, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, H₂Me₂Si₂I₂, EtSiI₃, Et₂SiI₂, Et₃SiI, Et₂Si₂I₄, Et₄Si₂I₂ and HEtSiI₂, including any combinations thereof.

The nitrogen gas may include at least one of N₂, NO, N₂O NO₂, N₂H₄, NH₃ and N₂/H₂ mixture. The oxygen gas may include at least one of O₂, CO, CO₂, N₂O and O₃

The plasma may be supplied through in-situ plasma generated in a reaction space on a substrate on which the thin film is deposited, or remote plasma generated outside the reaction space may be transported and supplied to the reaction space.

A silicon oxynitride (SiON) film having a desired thickness may be deposited by repeating the first gas supply cycle (m cycle) and the second gas supply cycle (n cycle). In this case, the first gas supply cycle (m cycle) and the second gas supply cycle (n cycle) may be alternately repeated, or repeating of the first gas supply cycle (m cycle) for first plural times and repeating of the second gas supply cycle (n cycle) for second plural times may be alternately repeated. Herein, the first plural times and the second plural times may be the same as or different from each other.

Like this, an oxygen content and a nitrogen content in the silicon oxynitride (SiON) film may be adjusted by adjusting the number of repetition of the first gas supply cycle (m cycle) and the second gas supply cycle (n cycle). Accordingly, thin films having various compositions may be deposited according to the application purpose of the thin film.

According to the method of depositing the thin film according to the exemplary embodiment of the present invention, the source gas and the reaction gas in an inactive state may be supplied to each reactor before plasma is supplied to each reactor of a multi-chamber deposition device, and plasma may be then supplied on a predetermined cycle of time to minimize a pressure fluctuation in the reactor and stably supply plasma to each reactor. Therefore, thin film can be deposited on a substrate in each reactor with reproducibility among the reactors. Further, the oxygen content and the nitrogen content in the silicon oxynitride film may be adjusted by appropriately adjusting the number of repetition of the first supply cycle and the second supply cycle.

Like this, according to the method of depositing the thin film according to the exemplary embodiment of the present invention, unlike a known plasma enhanced chemical vapor deposition method (PECVD), process gases may be sequentially supplied to the reactor by using a plasma enhanced atomic layer deposition method (PEALD) and the reaction gas may be supplied in advance before plasma is supplied to minimize a pressure fluctuation in each reactor. Thereby, uniformity of the thin film may be improved among the reactors, and a thickness of the thin film may be precisely controlled. Accordingly, uniformity of the deposited thin film may be improved in each chamber of the multi-chamber deposition device including a plurality of reactors to improve process reproducibility among reactors.

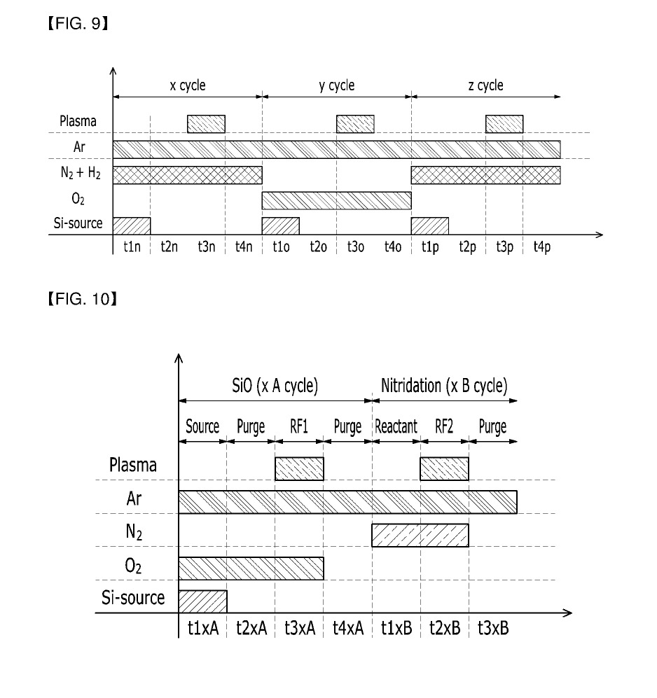

A method of depositing a thin film according to another exemplary embodiment of the present invention will be described with reference to FIG. 9.

FIG. 9 is a timing chart showing a gas supply cycle to deposit a thin film according to an exemplary embodiment of the present invention.

In this embodiment, a first gas supply cycle (x cycle) and a second gas supply cycle (y cycle) are the same as those of FIG. 6. but a third gas supply cycle (z cycle) is further included. That is the first gas supply cycle (x cycle) includes a first to fourth sub-period t1n, t2n, t3n and t4n and the second gas supply cycle (y cycle) includes a fifth to eighth sub-period t1o, t2o, t3o and t4o. In addition the third gas supply cycle (z cycle) includes a ninth to twelfth sub-period t1p, t2p, t3p and t4p. The sequence of the third gas supply cycle (z cycle) is the same as that of the first gas supply cycle (x cycle).

In detail, in the first gas supply cycle (x cycle), while nitrogen gas (N₂), hydrogen gas (H₂) and argon (Ar) gas are supplied, a silicon source gas (Si source gas) is supplied for a first sub-periods t1n. For a second sub-period t2n, the nitrogen gas (N₂), hydrogen gas (H₂) and argon (Ar) gas are continuously supplied but the silicon source gas (Si source gas) is no more supplied. While the nitrogen gas (N₂), hydrogen gas (H₂) and argon (Ar) gas are supplied, plasma is supplied for a third sub-period t3n. The nitrogen gas (N₂), hydrogen gas (H₂) and argon (Ar) gas are continuously supplied but the plasma is no more supplied for a fourth sub-period t4n. A silicon nitride (SiN) film having a desired thickness may be deposited by repeating the first gas supply cycle (x cycle).

In the second gas supply cycle (y cycle), while the oxygen gas (O₂) and argon (Ar) gas are supplied, the silicon source gas (Si source gas) is supplied for a fifth sub-period t1o. For a sixth sub-period t2j, the oxygen gas (O₂) and argon (Ar) gas are continuously supplied but the silicon source gas (Si source gas) is no more supplied. While the oxygen gas (O₂) and argon (Ar) gas are supplied, plasma is supplied for a seventh sub-period t3o. The oxygen gas (O₂) and argon (Ar) gas are continuously supplied but the plasma is no more supplied for a eighth sub-period t4o. A silicon oxide (SiO) film having a desired thickness may be deposited by repeating the second gas supply cycle (y cycle).

In the third gas supply cycle (z cycle), while the nitrogen gas (N₂), hydrogen gas (H₂) and argon (Ar) gas are supplied, a silicon source gas (Si source gas) is supplied for a ninth sub-periods t1p. For a tenth sub-period t2p, the nitrogen gas (N₂), hydrogen gas (H₂) and argon (Ar) gas are continuously supplied but the silicon source gas (Si source gas) is no more supplied. While the nitrogen gas (N₂), hydrogen gas (H₂) and argon (Ar) gas are supplied, plasma is supplied for a eleventh sub-period t3p. The nitrogen gas (N₂), hydrogen gas (H₂) and argon (Ar) gas are continuously supplied but the plasma is no more supplied for a twelfth sub-period t4p. A silicon nitride (SiN) film having a desired thickness may be deposited by repeating the third gas supply cycle (z cycle).

Like this, according to the gas supply cycle of the method of depositing a thin film according to the present exemplary embodiment, the argon gas (Ar), nitrogen gas (N₂), hydrogen gas (H₂) and oxygen gas (O₂) in an inactive state are used as a purge gas. Those gases (Ar, N₂, H₂, O₂) in an inactive state do not react with the silicon source gas (Si source gas). The nitrogen gas (N₂), hydrogen gas (H₂) and oxygen gas (O₂) are activated by supplying plasma to react with the silicon source gas (Si source gas). Accordingly, the nitrogen gas (N₂), hydrogen gas (H₂) and oxygen gas (O₂) are activated by supplying plasma to work as a reaction gas.

Herein, the silicon source gas may include at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DIPAS, SiH₃N(iPr)₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; TEOS, Si(OEt)₄; SiCl₄; HCD, Si₂Cl₆; MCS, SiH₃Cl; DCS, SiH₂Cl₂; 3DMAS, SiH(N(Me)₂)₃; BEMAS, SiH₂[N(Et)(Me)]₂; AHEAD, Si₂(NHEt)₆; TEAS, Si(NHEt)₄; and Si₃H₈.

The silicon source gas may comprise one or more of the following: SiI₄, HSiI₃, H₂SiI₂, H₃SiI, Si₂I₆, HSi₂I₅, H₂Si₂I₄, H₃Si₂I₃, H₄Si₂I₂, H₅Si₂I, Si₃I₈, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, HMe₂SiI, HMeSi₂I₄, HMe₂Si₂I₃, HMe₃Si₂I₂, HMe₄Si₂I, H₂MeSiI, H₂MeSi₂I₃, H₂Me₂Si₂I₂, H₂Me₃Si₂I, H₃MeSi₂I₂, H₃Me₂Si₂I, H₄MeSi₂I, EtSiI₃, Et₂SiI₂, Et₃SiI, EtSi₂I₅, Et₂Si₂I₄, Et₃Si₂I₃, Et₄Si₂I₂, Et₅Si₂I, HEtSiI₂, HEt₂SiI, HEtSi₂I₄, HEt₂Si₂I₃, HEt₃Si₂I₂, HEt₄Si₂I, H₂EtSiI, H₂EtSi₂I₃, H₂Et₂Si₂I₂, H₂Et₃Si₂I, H₃EtSi₂I₂, H₃Et₂Si₂I and H₄EtSi₂I.

The silicon source gas may comprise one or more of the following: EtMeSiI₂, Et₂MeSiI, EtMe₂SiI, EtMeSi₂I₄, Et₂MeSi₂I₃, EtMe₂Si₂I₃, Et₃MeSi₂I₂, Et₂Me₂Si₂I₂, EtMe₃Si₂I₂, Et₄MeSi₂I, Et₃Me₂Si₂I, Et₂Me₃Si₂I, EtMe₄Si₂I, HEtMeSiI, HEtMeSi₂I₃, HEt₂MeSi₂I₂, HEtMe₂Si₂I₂, HEt₃MeSi₂I, HEt₂Me₂Si₂I, HEtMe₃Si₂I, H₂EtMeSi₂I₂, H₂Et₂MeSi₂I, H₂EtMe₂Si₂I, H₃EtMeSi₂I.

The silicon source gas may comprise two, three, four, five, six, seven, eight, nine, ten, eleven, twelve, thirteen, fourteen, fifteen, sixteen, seventeen, eighteen, nineteen or more compounds selected from HSiI₃, H₂SiI₂, H₃SiI, H₂Si₂I₄, H₄Si₂I₂, H₅Si₂I, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, H₂Me₂Si₂I₂, EtSiI₃, Et₂SiI₂, Et₃SiI, Et₂Si₂I₄, Et₄Si₂I₂ and HEtSiI₂, including any combinations thereof.

The nitrogen gas may include at least one of N₂, NO, N₂O NO₂, N₂H₄, NH₃ and N₂/H₂ mixture. The oxygen gas may include at least one of O₂, CO, CO₂, N₂O and O₃

The plasma may be is supplied through in-situ plasma generated in a reaction space on a substrate on which the thin film is deposited, or remote plasma generated outside the reaction space may be transported and supplied to the reaction space.

A silicon oxynitride (SiON) film having a desired thickness may be deposited by repeating the first gas supply cycle (x cycle), the second gas supply cycle (y cycle) and the third gas supply cycle (z cycle). In this case, the first gas supply cycle (x cycle), the second gas supply cycle (y cycle) and the third gas supply cycle (z cycle) may be alternately repeated, or repeating of the first gas supply cycle (x cycle) for first plural times, repeating of the second gas supply cycle (y cycle) for second plural times and repeating of the third gas supply cycle (z cycle) for third plural times may be alternately repeated. Herein, the first plural times, the second plural times and the third plural times may be the same as or different from each other.

Like this, an oxygen content and a nitrogen content in the silicon oxynitride (SiON) film may be adjusted by adjusting the number of repetition of the first gas supply cycle (x cycle), the second gas supply cycle (y cycle) and the third gas supply cycle (z cycle). Accordingly, thin films having various compositions may be deposited according to the application purpose of the thin film.

According to the method of depositing the thin film according to the exemplary embodiment of the present invention, the source gas and the reaction gas in an inactive state may be supplied to each reactor before plasma is supplied to each reactor of a multi-chamber deposition device, and plasma may be then supplied on a predetermined cycle of time to minimize a pressure fluctuation in the reactor and stably supply plasma to each reactor. Therefore, thin film can be deposited on a substrate in each reactor with reproducibility among the reactors. Further, the oxygen content and the nitrogen content in the silicon oxynitride film may be adjusted by appropriately adjusting the number of repetition of the first supply cycle and the second supply cycle.

Like this, according to the method of depositing the thin film according to the exemplary embodiment of the present invention, unlike a known plasma enhanced chemical vapor deposition method (PECVD), process gases may be sequentially supplied to the reactor by using a plasma enhanced atomic layer deposition method (PEALD) and the reaction gas may be supplied in advance before plasma is supplied to minimize a pressure fluctuation in each reactor. Thereby, uniformity of the thin film may be improved among the reactors, and a thickness of the thin film may be precisely controlled. Accordingly, uniformity of the deposited thin film may be improved in each chamber of the multi-chamber deposition device including a plurality of reactors to improve process reproducibility among reactors.

A method to deposit a thin film according to another exemplary embodiment of the present invention will be described with reference to FIG. 10.

The method of FIG. 10 includes a first gas supply cycle (xA cycle) and a second gas supply cycle (xB cycle). The first gas supply cycle (xA cycle) includes a first to fourth sub-periods t1xA, t2xA, t3xA and t4xA and the second gas supply cycle (xB cycle) includes a fifth to seventh sub-periods t1xB, t2xB and t3xB.

The first gas supply cycle (xA cycle) will be described. While oxygen gas (O₂) and argon (Ar) gas are supplied, a silicon source gas (Si source gas) is supplied for the first sub-period t1xA. For the second sub-period t2xA, the oxygen gas (O₂) and argon (Ar) gas are continuously supplied but the silicon source gas (Si source gas) is no more supplied. While the oxygen gas (O₂) and argon (Ar) gas are supplied, plasma is supplied for the third sub-period t3xA. The argon (Ar) gas is continuously supplied but the oxygen gas (O₂) and the plasma are no more supplied for the fourth sub-period t4xA. A silicon nitride (SiN) film having a desired thickness may be deposited by repeating the first gas supply cycle (xA cycle).

The second gas supply cycle (xB cycle) will be described. The nitrogen gas (N₂) and argon (Ar) gas are supplied for the fifth sub-period t1xB. For the sixth sub-period t2xB, the plasma is supplied along with the nitrogen gas (N₂) and argon (Ar) gas. For the seventh sub-period t3xB, the argon (Ar) gas is supplied but the other gases and plasma are not supplied.

Like this, according to the gas supply cycle of the method of depositing a thin film according to the present exemplary embodiment, the argon gas (Ar), nitrogen gas (N₂), and oxygen gas (O₂) in an inactive state are used as a purge gas. Those gases (Ar, N₂, O₂) in an inactive state do not react with the silicon source gas (Si source gas). The nitrogen gas (N₂) and oxygen gas (O₂) are activated by supplying plasma to react with the silicon source gas (Si source gas). Accordingly, the nitrogen gas (N₂) and oxygen gas (O₂) are activated by supplying plasma to work as a reaction gas.

Herein, the silicon source gas may include at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DIPAS, SiH₃N(iPr)₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; TEOS, Si(OEt)₄; SiCl₄; HCD, Si₂Cl₆; MCS, SiH₃Cl; DCS, SiH₂Cl₂; 3DMAS, SiH(N(Me)₂)₃; BEMAS, SiH₂[N(Et)(Me)]₂; AHEAD, Si₂(NHEt)₆; TEAS, Si(NHEt)₄; and Si₃H₈.

The silicon source gas may comprise one or more of the following: SiI₄, HSiI₃, H₂SiI₂, H₃SiI, Si₂I₆, HSi₂I₅, H₂Si₂I₄, H₃Si₂I₃, H₄Si₂I₂, H₅Si₂I, Si₃I₈, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, HMe₂SiI, HMeSi₂I₄, HMe₂Si₂I₃, HMe₃Si₂I₂, HMe₄Si₂I, H₂MeSiI, H₂MeSi₂I₃, H₂Me₂Si₂I₂, H₂Me₃Si₂I, H₃MeSi₂I₂, H₃Me₂Si₂I, H₄MeSi₂I, EtSiI₃, Et₂SiI₂, Et₃SiI, EtSi₂I₅, Et₂Si₂I₄, Et₃Si₂I₃, Et₄Si₂I₂, Et₅Si₂I, HEtSiI₂, HEt₂SiI, HEtSi₂I₄, HEt₂Si₂I₃, HEt₃Si₂I₂, HEt₄Si₂I, H₂EtSiI, H₂EtSi₂I₃, H₂Et₂Si₂I₂, H₂Et₃Si₂I, H₃EtSi₂I₂, H₃Et₂Si₂I and H₄EtSi₂I.

The silicon source gas may comprise one or more of the following: EtMeSiI₂, Et₂MeSiI, EtMe₂SiI, EtMeSi₂I₄, Et₂MeSi₂I₃, EtMe₂Si₂I₃, Et₃MeSi₂I₂, Et₂Me₂Si₂I₂, EtMe₃Si₂I₂, Et₄MeSi₂I, Et₃Me₂Si₂I, Et₂Me₃Si₂I, EtMe₄Si₂I, HEtMeSiI, HEtMeSi₂I₃, HEt₂MeSi₂I₂, HEtMe₂Si₂I₂, HEt₃MeSi₂I, HEt₂Me₂Si₂I, HEtMe₃Si₂I, H₂EtMeSi₂I₂, H₂Et₂MeSi₂I, H₂EtMe₂Si₂I, H₃EtMeSi₂I.

The silicon source gas may comprise two, three, four, five, six, seven, eight, nine, ten, eleven, twelve, thirteen, fourteen, fifteen, sixteen, seventeen, eighteen, nineteen or more compounds selected from HSiI₃, H₂SiI₂, H₃SiI, H₂Si₂I₄, H₄Si₂I₂, H₅Si₂I, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, H₂Me₂Si₂I₂, EtSiI₃, Et₂SiI₂, Et₃SiI, Et₂Si₂I₄, Et₄Si₂I₂ and HEtSiI₂, including any combinations thereof.

The nitrogen gas may include at least one of N₂, NO, N₂O NO₂, N₂H₄, NH₃ and N₂/H₂ mixture. The oxygen gas may include at least one of O₂, CO, CO₂, N₂O and O₃

The plasma may be supplied through in-situ plasma generated in a reaction space on a substrate on which the thin film is deposited, or remote plasma generated outside the reaction space may be transported and supplied to the reaction space.

A silicon oxynitride (SiON) film having a desired thickness may be deposited by repeating the first gas supply cycle (xA cycle) and the second gas supply cycle (xB cycle). In this case, the first gas supply cycle (xA cycle) and the second gas supply cycle (xB cycle) may be alternately repeated, or repeating of the first gas supply cycle (xA cycle) for first plural times and repeating of the second gas supply cycle (xB cycle) for second plural times may be alternately repeated. Herein, the first plural times and the second plural times may be the same as or different from each other.

Like this, an oxygen content and a nitrogen content in the silicon oxynitride (SiON) film may be adjusted by adjusting the number of repetition of the first gas supply cycle (xA cycle) and the second gas supply cycle (xB cycle). Accordingly, thin films having various compositions may be deposited according to the application purpose of the thin film.

According to the method of depositing the thin film according to the exemplary embodiment of the present invention, the source gas and the reaction gas in an inactive state may be supplied to each reactor before plasma is supplied to each reactor of a multi-chamber deposition device, and plasma may be then supplied on a predetermined cycle of time to minimize a pressure fluctuation in the reactor and stably supply plasma to each reactor. Therefore, thin film can be deposited on a substrate in each reactor with reproducibility among the reactors. Further, the oxygen content and the nitrogen content in the silicon oxynitride film may be adjusted by appropriately adjusting the number of repetition of the first supply cycle and the second supply cycle.

Like this, according to the method of depositing the thin film according to the exemplary embodiment of the present invention, unlike a known plasma enhanced chemical vapor deposition method (PECVD), process gases may be sequentially supplied to the reactor by using a plasma enhanced atomic layer deposition method (PEALD) and the reaction gas may be supplied in advance before plasma is supplied to minimize a pressure fluctuation in each reactor. Thereby, uniformity of the thin film may be improved among the reactors, and a thickness of the thin film may be precisely controlled. Accordingly, uniformity of the deposited thin film may be improved in each chamber of the multi-chamber deposition device including a plurality of reactors to improve process reproducibility among reactors.

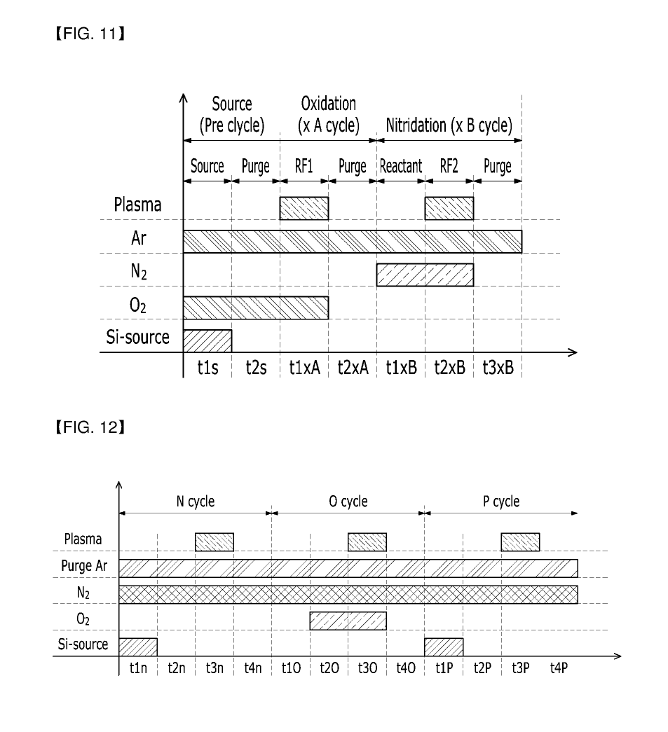

A method to deposit a thin film according to another exemplary embodiment of the present invention will be described with reference to FIG. 11.

The method of FIG. 11 includes a first gas supply cycle (pre cycle), a second gas supply cycle (xA cycle) and a third gas supply cycle (xB cycle). The first gas supply cycle (pre cycle) includes a first and a second sub-periods t1 s and t2s, the second gas supply cycle (xA cycle) includes a third and a fourth sub-periods t1xA and t2xA and the third gas supply cycle (xB cycle) includes a fifth to seventh sub-periods t1xB, t2xB and t3xB.

The first gas supply cycle (pre cycle) will be described. While oxygen gas (O₂) and argon (Ar) gas are supplied, a silicon source gas (Si source gas) is supplied for the first sub-period t1s. For the second sub-period t2s, the oxygen gas (O₂) and argon (Ar) gas are continuously supplied but the silicon source gas (Si source gas) is no more supplied.

The second gas supply cycle (xA cycle) will be described. While the oxygen gas (O₂) and argon (Ar) gas are supplied, plasma is supplied for the third sub-period t1xA. The argon (Ar) gas is continuously supplied but the oxygen gas (O₂) and the plasma are no more supplied for the fourth sub-period t2xA. A silicon nitride (SiN) film having a desired thickness may be deposited by repeating the second gas supply cycle (xA cycle).

The third gas supply cycle (xB cycle) will be described. The nitrogen gas (N₂) and argon (Ar) gas are supplied for the fifth sub-period t1xB. For the sixth sub-period t2xB, the plasma is supplied along with the nitrogen gas (N₂) and argon (Ar) gas. For the seventh sub-period t3xB, the argon (Ar) gas is supplied but the other gases and plasma are not supplied.

Like this, according to the gas supply cycle of the method of depositing a thin film according to the present exemplary embodiment, the argon gas (Ar), nitrogen gas (N₂), and oxygen gas (O₂) in an inactive state are used as a purge gas. Those gases (Ar, N₂, O₂) in an inactive state do not react with the silicon source gas (Si source gas). The nitrogen gas (N₂) and oxygen gas (O₂) are activated by supplying plasma to react with the silicon source gas (Si source gas). Accordingly, the nitrogen gas (N₂) and oxygen gas (O₂) are activated by supplying plasma to work as a reaction gas.

Herein, the silicon source gas may include at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DIPAS, SiH₃N(iPr)₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; TEOS, Si(OEt)₄; SiCl₄; HCD, Si₂Cl₆; MCS, SiH₃Cl; DCS, SiH₂Cl₂; 3DMAS, SiH(N(Me)₂)₃; BEMAS, SiH₂[N(Et)(Me)]₂; AHEAD, Si₂(NHEt)₆; TEAS, Si(NHEt)₄; and Si₃H₈.

The silicon source gas may comprise one or more of the following: SiI₄, HSiI₃, H₂SiI₂, H₃SiI, Si₂I₆, HSi₂I₅, H₂Si₂I₄, H₃Si₂I₃, H₄Si₂I₂, H₅Si₂I, Si₃I₈, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, HMe₂SiI, HMeSi₂I₄, HMe₂Si₂I₃, HMe₃Si₂I₂, HMe₄Si₂I, H₂MeSiI, H₂MeSi₂I₃, H₂Me₂Si₂I₂, H₂Me₃Si₂I, H₃MeSi₂I₂, H₃Me₂Si₂I, H₄MeSi₂I, EtSiI₃, Et₂SiI₂, Et₃SiI, EtSi₂I₅, Et₂Si₂I₄, Et₃Si₂I₃, Et₄Si₂I₂, Et₅Si₂I, HEtSiI₂, HEt₂SiI, HEtSi₂I₄, HEt₂Si₂I₃, HEt₃Si₂I₂, HEt₄Si₂I, H₂EtSiI, H₂EtSi₂I₃, H₂Et₂Si₂I₂, H₂Et₃Si₂I, H₃EtSi₂I₂, H₃Et₂Si₂I and H₄EtSi₂I.

The silicon source gas may comprise one or more of the following: EtMeSiI₂, Et₂MeSiI, EtMe₂SiI, EtMeSi₂I₄, Et₂MeSi₂I₃, EtMe₂Si₂I₃, Et₃MeSi₂I₂, Et₂Me₂Si₂I₂, EtMe₃Si₂I₂, Et₄MeSi₂I, Et₃Me₂Si₂I, Et₂Me₃Si₂I, EtMe₄Si₂I, HEtMeSiI, HEtMeSi₂I₃, HEt₂MeSi₂I₂, HEtMe₂Si₂I₂, HEt₃MeSi₂I, HEt₂Me₂Si₂I, HEtMe₃Si₂I, H₂EtMeSi₂I₂, H₂Et₂MeSi₂I, H₂EtMe₂Si₂I, H₃EtMeSi₂I.

The silicon source gas may comprise two, three, four, five, six, seven, eight, nine, ten, eleven, twelve, thirteen, fourteen, fifteen, sixteen, seventeen, eighteen, nineteen or more compounds selected from HSiI₃, H₂SiI₂, H₃SiI, H₂Si₂I₄, H₄Si₂I₂, H₅Si₂I, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, H₂Me₂Si₂I₂, EtSiI₃, Et₂SiI₂, Et₃SiI, Et₂Si₂I₄, Et₄Si₂I₂ and HEtSiI₂, including any combinations thereof.

The nitrogen gas may include at least one of N₂, NO, N₂O NO₂, N₂H₄, NH₃ and N₂/H₂ mixture. The oxygen gas may include at least one of O₂, CO, CO₂, N₂O and O₃

The plasma may be supplied through in-situ plasma generated in a reaction space on a substrate on which the thin film is deposited, or remote plasma generated outside the reaction space may be transported and supplied to the reaction space.

A silicon oxynitride (SiON) film having a desired thickness may be deposited by repeating the second gas supply cycle (xA cycle) and the third gas supply cycle (xB cycle). In this case, the second gas supply cycle (xA cycle) and the third gas supply cycle (xB cycle) may be alternately repeated, or repeating of the second gas supply cycle (xA cycle) for first plural times and repeating of the third gas supply cycle (xB cycle) for second plural times may be alternately repeated. Herein, the first plural times and the second plural times may be the same as or different from each other.

Like this, an oxygen content and a nitrogen content in the silicon oxynitride (SiON) film may be adjusted by adjusting the number of repetition of the second gas supply cycle (xA cycle) and the third gas supply cycle (xB cycle). Accordingly, thin films having various compositions may be deposited according to the application purpose of the thin film.

According to the method of depositing the thin film according to the exemplary embodiment of the present invention, the source gas and the reaction gas in an inactive state may be supplied to each reactor before plasma is supplied to each reactor of a multi-chamber deposition device, and plasma may be then supplied on a predetermined cycle of time to minimize a pressure fluctuation in the reactor and stably supply plasma to each reactor. Therefore, thin film can be deposited on a substrate in each reactor with reproducibility among the reactors. Further, the oxygen content and the nitrogen content in the silicon oxynitride film may be adjusted by appropriately adjusting the number of repetition of the first supply cycle and the second supply cycle.

Like this, according to the method of depositing the thin film according to the exemplary embodiment of the present invention, unlike a known plasma enhanced chemical vapor deposition method (PECVD), process gases may be sequentially supplied to the reactor by using a plasma enhanced atomic layer deposition method (PEALD) and the reaction gas may be supplied in advance before plasma is supplied to minimize a pressure fluctuation in each reactor. Thereby, uniformity of the thin film may be improved among the reactors, and a thickness of the thin film may be precisely controlled. Accordingly, uniformity of the deposited thin film may be improved in each chamber of the multi-chamber deposition device including a plurality of reactors to improve process reproducibility among reactors.

A method to deposit a thin film according to another exemplary embodiment of the present invention will be described with reference to FIG. 12.

The method of FIG. 12 includes a first gas supply cycle (N cycle), a second gas supply cycle (O cycle) and a third gas supply cycle (P cycle). The first gas supply cycle (N cycle) includes a first to fourth sub-period t1n, t2n, t3n and t4n and the second gas supply cycle (O cycle) includes a fifth to eighth sub-period t1o, t2o, t3o and t4o. In addition the third gas supply cycle (P cycle) includes a ninth to twelfth sub-period t1p, t2p, t3p and t4p.

In detail, in the first gas supply cycle (N cycle), while nitrogen gas (N₂) and argon (Ar) gas are supplied, a silicon source gas (Si source gas) is supplied for a first sub-periods t1n. For a second sub-period t2n, the nitrogen gas (N₂) and argon (Ar) gas are continuously supplied but the silicon source gas (Si source gas) is no more supplied. While the nitrogen gas (N₂) and argon (Ar) gas are supplied, plasma is supplied for a third sub-period t3n. The nitrogen gas (N₂) and argon (Ar) gas are continuously supplied but the plasma is no more supplied for a fourth sub-period t4n. A silicon nitride (SiN) film having a desired thickness may be deposited by repeating the first gas supply cycle (N cycle).

In the second gas supply cycle (O cycle), the nitrogen gas (N₂) and argon (Ar) gas are continuously supplied for a fifth sub-period t1o. For a sixth sub-period t2j, oxygen gas (O₂) is supplied along with the nitrogen gas (N₂) and argon (Ar) gas. While the oxygen gas (O₂), nitrogen gas (N₂) and argon (Ar) gas are supplied, the plasma is supplied for a seventh sub-period t3o. The nitrogen gas (N₂) and argon (Ar) gas are continuously supplied but the plasma and oxygen gas (O₂) are no more supplied for a eighth sub-period t4o. A silicon oxide (SiO) film having a desired thickness may be deposited by repeating the second gas supply cycle (O cycle).

In the third gas supply cycle (P cycle), while the nitrogen gas (N₂) and argon (Ar) gas are supplied, a silicon source gas (Si source gas) is supplied for a ninth sub-periods t1p. For a tenth sub-period t2p, the nitrogen gas (N₂) and argon (Ar) gas are continuously supplied but the silicon source gas (Si source gas) is no more supplied. While the nitrogen gas (N₂) and argon (Ar) gas are supplied, the plasma is supplied for a eleventh sub-period t3p. The nitrogen gas (N₂) and argon (Ar) gas are continuously supplied but the plasma is no more supplied for a twelfth sub-period t4p. A silicon nitride (SiN) film having a desired thickness may be deposited by repeating the third gas supply cycle (P cycle).

Like this, according to the gas supply cycle of the method of depositing a thin film according to the present exemplary embodiment, the argon gas (Ar), nitrogen gas (N₂), and oxygen gas (O₂) in an inactive state are used as a purge gas. Those gases (Ar, N₂, O₂) in an inactive state do not react with the silicon source gas (Si source gas). The nitrogen gas (N₂) and oxygen gas (O₂) are activated by supplying plasma to react with the silicon source gas (Si source gas). Accordingly, the nitrogen gas (N₂) and oxygen gas (O₂) are activated by supplying plasma to work as a reaction gas.

Herein, the silicon source gas may include at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DIPAS, SiH₃N(iPr)₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; TEOS, Si(OEt)₄; SiCl₄; HCD, Si₂Cl₆; MCS, SiH₃Cl; DCS, SiH₂Cl₂; 3DMAS, SiH(N(Me)₂)₃; BEMAS, SiH₂[N(Et)(Me)]₂; AHEAD, Si₂(NHEt)₆; TEAS, Si(NHEt)₄; and Si₃H₈.

The silicon source gas may comprise one or more of the following: SiI₄, HSiI₃, H₂SiI₂, H₃SiI, Si₂I₆, HSi₂I₅, H₂Si₂I₄, H₃Si₂I₃, H₄Si₂I₂, H₅Si₂I, Si₃I₈, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, HMe₂SiI, HMeSi₂I₄, HMe₂Si₂I₃, HMe₃Si₂I₂, HMe₄Si₂I, H₂MeSiI, H₂MeSi₂I₃, H₂Me₂Si₂I₂, H₂Me₃Si₂I, H₃MeSi₂I₂, H₃Me₂Si₂I, H₄MeSi₂I, EtSiI₃, Et₂SiI₂, Et₃SiI, EtSi₂I₅, Et₂Si₂I₄, Et₃Si₂I₃, Et₄Si₂I₂, Et₅Si₂I, HEtSiI₂, HEt₂SiI, HEtSi₂I₄, HEt₂Si₂I₃, HEt₃Si₂I₂, HEt₄Si₂I, H₂EtSiI, H₂EtSi₂I₃, H₂Et₂Si₂I₂, H₂Et₃Si₂I, H₃EtSi₂I₂, H₃Et₂Si₂I and H₄EtSi₂I.

The silicon source gas may comprise one or more of the following: EtMeSiI₂, Et₂MeSiI, EtMe₂SiI, EtMeSi₂I₄, Et₂MeSi₂I₃, EtMe₂Si₂I₃, Et₃MeSi₂I₂, Et₂Me₂Si₂I₂, EtMe₃Si₂I₂, Et₄MeSi₂I, Et₃Me₂Si₂I, Et₂Me₃Si₂I, EtMe₄Si₂I, HEtMeSiI, HEtMeSi₂I₃, HEt₂MeSi₂I₂, HEtMe₂Si₂I₂, HEt₃MeSi₂I, HEt₂Me₂Si₂I, HEtMe₃Si₂I, H₂EtMeSi₂I₂, H₂Et₂MeSi₂I, H₂EtMe₂Si₂I, H₃EtMeSi₂I.

The silicon source gas may comprise two, three, four, five, six, seven, eight, nine, ten, eleven, twelve, thirteen, fourteen, fifteen, sixteen, seventeen, eighteen, nineteen or more compounds selected from HSiI₃, H₂SiI₂, H₃SiI, H₂Si₂I₄, H₄Si₂I₂, H₅Si₂I, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, H₂Me₂Si₂I₂, EtSiI₃, Et₂SiI₂, Et₃SiI, Et₂Si₂I₄, Et₄Si₂I₂ and HEtSiI₂, including any combinations thereof.

The nitrogen gas may include at least one of N₂, NO, N₂O NO₂, N₂H₄, NH₃ and N₂/H₂ mixture. The oxygen gas may include at least one of O₂, CO, CO₂, N₂O and O₃

The plasma may be supplied through in-situ plasma generated in a reaction space on a substrate on which the thin film is deposited, or remote plasma generated outside the reaction space may be transported and supplied to the reaction space.

A silicon oxynitride (SiON) film having a desired thickness may be deposited by repeating the first gas supply cycle (N cycle), the second gas supply cycle (O cycle) and the third gas supply cycle (P cycle). In this case, the first gas supply cycle (N cycle), the second gas supply cycle (O cycle) and the third gas supply cycle (P cycle) may be alternately repeated, or repeating of the first gas supply cycle (N cycle) for first plural times, repeating of the second gas supply cycle (O cycle) for second plural times and repeating of the third gas supply cycle (P cycle) for third plural times may be alternately repeated. Herein, the first plural times, the second plural times and the third plural times may be the same as or different from each other.

Like this, an oxygen content and a nitrogen content in the silicon oxynitride (SiON) film may be adjusted by adjusting the number of repetition of the first gas supply cycle (N cycle), the second gas supply cycle (O cycle) and the third gas supply cycle (P cycle). Accordingly, thin films having various compositions may be deposited according to the application purpose of the thin film.

According to the method of depositing the thin film according to the exemplary embodiment of the present invention, the source gas and the reaction gas in an inactive state may be supplied to each reactor before plasma is supplied to each reactor of a multi-chamber deposition device, and plasma may be then supplied on a predetermined cycle of time to minimize a pressure fluctuation in the reactor and stably supply plasma to each reactor. Therefore, thin film can be deposited on a substrate in each reactor with reproducibility among the reactors. Further, the oxygen content and the nitrogen content in the silicon oxynitride film may be adjusted by appropriately adjusting the number of repetition of the first supply cycle and the second supply cycle.

Like this, according to the method of depositing the thin film according to the exemplary embodiment of the present invention, unlike a known plasma enhanced chemical vapor deposition method (PECVD), process gases may be sequentially supplied to the reactor by using a plasma enhanced atomic layer deposition method (PEALD) and the reaction gas may be supplied in advance before plasma is supplied to minimize a pressure fluctuation in each reactor. Thereby, uniformity of the thin film may be improved among the reactors, and a thickness of the thin film may be precisely controlled. Accordingly, uniformity of the deposited thin film may be improved in each chamber of the multi-chamber deposition device including a plurality of reactors to improve process reproducibility among reactors.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of depositing a thin film, comprising:
supplying a purge gas, a source gas and a first reaction gas into a plurality of reactors for a first sub-period,
stopping supplying of the source gas, and supplying the purge gas and the first reaction gas into the plurality of reactors for a second sub-period,
supplying the purge gas, the first reaction gas and plasma into the plurality of reactors for a third sub-period,
supplying the purge gas and a second reaction gas into the plurality of reactors for a fifth sub-period, and
supplying the purge gas, the second reaction gas and the plasma into the plurality of reactors for a seventh sub-period.

2. The method of claim 1, further comprising:
supplying of the source gas into the plurality of reactors for the fifth sub-period.

3. The method of claim 2, wherein:
the source gas is a precursor including silicon,
the first reaction gas is a gas including nitrogen, and
the second reaction gas is a gas including oxygen.

4. The method of claim 2, wherein:
the source gas comprises at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DIPAS, SiH₃N(iPr)₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; TEOS, Si(OEt)₄; SiCl₄; HCD, Si₂Cl₆; MCS, SiH₃Cl; DCS, SiH₂Cl₂; 3DMAS, SiH(N(Me)₂)₃; BEMAS, SiH₂[N(Et)(Me)]₂; AHEAD, Si₂(NHEt)₆; TEAS, Si(NHEt)₄; and Si₃H₈.

5. The method of claim 2, wherein:
the source gas comprises at least one of SiI₄, HSiI₃, H₂SiI₂, H₃SiI, Si₂I₆, HSi₂I₅, H₂Si₂I₄, H₃Si₂I₃, H₄Si₂I₂, H₅Si₂I, Si₃I₈, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, HMe₂SiI, HMeSi₂I₄, HMe₂Si₂I₃, HMe₃Si₂I₂, HMe₄Si₂I, H₂MeSiI, H₂MeSi₂I₃, H₂Me₂Si₂I₂, H₂Me₃Si₂I, H₃MeSi₂I₂, H₃Me₂Si₂I, H₄MeSi₂I, EtSiI₃, Et₂SiI₂, Et₃SiI, EtSi₂I₅, Et₂Si₂I₄, Et₃Si₂I₃, Et₄Si₂I₂, Et₅Si₂I, HEtSiI₂, HEt₂SiI, HEtSi₂I₄, HEt₂Si₂I₃, HEt₃Si₂I₂, HEt₄Si₂I, H₂EtSiI, H₂EtSi₂I₃, H₂Et₂Si₂I₂, H₂Et₃Si₂I, H₃EtSi₂I₂, H₃Et₂Si₂I and H₄EtSi₂I.

6. The method of claim 2, wherein:
the source gas comprises at least one of EtMeSiI₂, Et₂MeSiI, EtMe₂SiI, EtMeSi₂I₄, Et₂MeSi₂I₃, EtMe₂Si₂I₃, Et₃MeSi₂I₂, Et₂Me₂Si₂I₂, EtMe₃Si₂I₂, Et₄MeSi₂I, Et₃Me₂Si₂I, Et₂Me₃Si₂I, EtMe₄Si₂I, HEtMeSiI, HEtMeSi₂I₃, HEt₂MeSi₂I₂, HEtMe₂Si₂I₂, HEt₃MeSi₂I, HEt₂Me₂Si₂I, HEtMe₃Si₂I, H₂EtMeSi₂I₂, H₂Et₂MeSi₂I, H₂EtMe₂Si₂I, H₃EtMeSi₂I.

7. The method of claim 2, wherein:
the silicon source gas comprises two, three, four, five, six, seven, eight, nine, ten, eleven, twelve, thirteen, fourteen, fifteen, sixteen, seventeen, eighteen, nineteen or more compounds selected from HSiI₃, H₂SiI₂, H₃SiI, H₂Si₂I₄, H₄Si₂I₂, H₅Si₂I, MeSiI₃, Me₂SiI₂, Me₃SiI, MeSi₂I₅, Me₂Si₂I₄, Me₃Si₂I₃, Me₄Si₂I₂, Me₅Si₂I, HMeSiI₂, H₂Me₂Si₂I₂, EtSiI₃, Et₂SiI₂, Et₃SiI, Et₂Si₂I₄, Et₄Si₂I₂ and HEtSiI₂, including any combinations thereof.

8. The method of claim 2, wherein:
the first reaction gas comprises at least one of N₂, NO, N₂O, NO₂, N₂H₂, NH₃ and N₂/H₂ mixture, and
the second reaction gas comprises at least one of O₂, CO, CO₂, N₂O and O₃.

9. The method of claim 2, wherein the purge gas comprises an inert gas.

10. The method of claim 1, wherein a first gas supply cycle including the first sub-period, the second sub-period, and the third sub-period, and a second gas supply cycle including the fifth sub-period and the seventh sub-period are alternately repeated.

11. The method of claim 10, wherein:
the first gas supply cycle further comprises supplying the purge gas and the first reaction gas into the plurality of reactors for a fourth sub-period, and
the second gas supply cycle further comprises supplying the purge gas and the second reaction gas into the plurality of reactors for a sixth sub-period and an eighth sub-period.

12. The method of claim 10, wherein:
the second gas supply cycle further comprises supplying the purge gas and the first reaction gas into the plurality of reactors for an eighth sub-period.

13. The method of claim 11, further comprising:
a third gas supply cycle comprising a same sequence of sub-periods as the first gas supply cycle.

14. The method of claim 1, comprising:
repeating a first gas supply cycle including the first sub-period, the second sub-period, and the third sub-period for first plural times, and
repeating a second gas supply cycle including the fifth sub-period and the seventh sub-period for second plural times,
wherein the repeating of the first gas supply cycle and the repeating of the second gas supply cycle are alternately repeated.

15. The method of claim 14, wherein the first plural times and the second plural times are the same as or different from each other.

16. The method of claim 15, wherein:
the first gas supply cycle further comprises supplying the purge gas and the first reaction gas into the plurality of reactors for a fourth sub-period, and
the second gas supply cycle further comprises supplying the purge gas and the second reaction gas into the plurality of reactors for an eighth sub-period.

17. The method of claim 1, wherein:
the first reaction gas comprises at least one of O₂, CO, CO₂, N₂O and O₃, and
the second reaction gas comprises at least one of N₂, NO, N₂O, NO₂, N₂H₂, NH₃ and N₂/H₂ mixture.

18. The method of claim 17, wherein the purge gas comprises an inert gas.

19. The method of claim 18, wherein a first gas supply cycle including the first sub-period, the second sub-period, and the third sub-period, and a second gas supply cycle including the fifth sub-period and the seventh sub-period are alternately repeated.

20. The method of claim 19, wherein:
the first gas supply cycle further comprises supplying the purge gas into the plurality of reactors for a fourth sub-period, and
the second gas supply cycle further comprises supplying the purge gas into the plurality of reactors for an eighth sub-period.

21. The method of claim 18, comprising:
repeating a first gas supply cycle including the first sub-period, the second sub-period, and the third sub-period for first plural times, and
repeating a second gas supply cycle including the fifth sub-period and the seventh sub-period for second plural times,
wherein the repeating of the first gas supply cycle and the repeating of the second gas supply cycle are alternately repeated.

22. The method of claim 21, wherein the first plural times and the second plural times are the same as or different from each other.

23. The method of claim 22, wherein:
the first gas supply cycle further comprises supplying the purge gas into the plurality of reactors for a fourth sub-period, and
the second gas supply cycle further comprises supplying the purge gas into the plurality of reactors for an eighth sub-period.

24. The method of claim 18, comprising:
repeating a first gas supply cycle including the first sub-period and the second sub-period for first plural times,
repeating a second gas supply cycle including the third sub-period for second plural times, and
repeating a third gas supply cycle including the fifth sub-period and the seventh sub-period for third plural times,
wherein the repeating of the first gas supply cycle, the repeating of the second gas supply cycle and the repeating of the third gas supply cycle are alternately repeated.

25. The method of claim 24, wherein the first plural times, the second plural times and the third plural times are the same as or different from each other.

26. The method of claim 25, wherein:
the second gas supply cycle further comprises supplying the purge gas into the plurality of reactors for a fourth sub-period, and
the third gas supply cycle further comprises supplying the purge gas into the plurality of reactors for an eighth sub-period.
